(19) United States
(12) Patent Application Publication
(10) Pub. No.: US 2026/0033270 A1
(43) Pub. Date: Jan. 29, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventor: Hitoshi NAKAI, Kyoto-shi (JP)

(21) Appl. No.: 19/263,070

(22) Filed: Jul. 8, 2025

(30) Foreign Application Priority Data
Jul. 29, 2024 (JP) 2024-122041
Mar. 11, 2025 (JP) 2025-038525

(51) Int. Cl. H01L 21/67; H01L 21/677; H01L 21/687

(52) U.S. Cl. CPC H01L 21/67057; H01L 21/67046; H01L 21/67051; H01L 21/67772; H01L 21/68742; H01L 21/68764

(57) ABSTRACT

A substrate processing apparatus includes a substrate holding portion, an immersion bath, a first supplying portion, and a moving mechanism. The substrate holding portion holds and rotates a substrate. The immersion bath stores a processing liquid, accommodates the substrate, and immerses the substrate in the processing liquid. The first supplying portion supplies the processing liquid to the immersion bath. The moving mechanism relatively moves the substrate holding portion and the immersion bath. The moving mechanism switches a state of the substrate between a non-immersion state in which the substrate is located outside the immersion bath and an immersion state in which the substrate is located inside the immersion bath and immersed in the processing liquid by moving the substrate holding portion or the immersion bath.

### CROSS REFERENCE TO RELATED APPLICATIONS

This application claims the benefit of priority to Japanese Patent Application No. 2024-122041 filed on Jul. 29, 2024 and Japanese Patent Application No. 2025-038525 filed on Mar. 11, 2025. The entire contents of these applications are hereby incorporated herein by reference.

### BACKGROUND OF THE INVENTION

### 1. Field of the Invention

The present invention relates to a substrate processing apparatus and a substrate processing method.

### 2. Description of Related Art

Conventionally, a substrate processing apparatus for processing a substrate is known. The substrate processing apparatus is suitably used for manufacturing a semiconductor substrate. The substrate processing apparatus processes a substrate by using a processing liquid such as a chemical liquid. As such a substrate processing apparatus, a single substrate processing type substrate processing apparatus that processes substrates one by one and a batch type substrate processing apparatus that processes a plurality of substrates by immersing the substrates in a processing bath at one time are known. For example, JP 2020-126886 A discloses a single substrate processing type substrate processing apparatus including a holding and rotating portion that holds and rotates a substrate, and an ejection portion that ejects a processing liquid to the substrate that is being rotated by the holding and rotating portion.

In a single substrate processing type substrate processing apparatus, substrates are processed one by one by supplying a processing liquid to a substrate while horizontally holding and rotating the substrate. In general, since a single substrate processing type substrate processing apparatus can be downsized compared with a batch type substrate processing apparatus, the consumption amount of a processing liquid can be reduced.

However, in a single substrate processing type substrate processing apparatus, since a processing liquid is continuously supplied to the substrate, there is a problem that the consumption amount of the processing liquid cannot be reduced much in a case where processing for a long time is required.

One of objects of the present invention is to provide a substrate processing apparatus and a substrate processing method capable of reducing the consumption amount of a processing liquid.

### SUMMARY OF THE INVENTION

According to one aspect of the present invention, a substrate processing apparatus includes a substrate holding portion, an immersion bath, a processing liquid supplying portion, and a moving mechanism. The substrate holding portion holds and rotates a substrate. The immersion bath stores a processing liquid, accommodates the substrate, and immerses the substrate in the processing liquid. The processing liquid supplying portion supplies the processing liquid to the immersion bath. The moving mechanism relatively moves the substrate holding portion and the immersion bath. The moving mechanism switches a state of the substrate between a non-immersion state in which the substrate is located outside the immersion bath and an immersion state in which the substrate is located inside the immersion bath and immersed in the processing liquid by moving the substrate holding portion or the immersion bath.

In a preferred embodiment, the substrate holding portion includes a base disposed above the substrate, and a plurality of chuck pins protruding downward from the base and holding a circumferential edge of the substrate.

In a preferred embodiment, the processing liquid supplying portion includes an upper nozzle that ejects the processing liquid toward an upper surface of the substrate. The upper nozzle is provided on the base.

In a preferred embodiment, the substrate holding portion rotates the substrate by a rotation of the base. The upper nozzle is disposed at a central portion of the base.

In a preferred embodiment, the processing liquid supplying portion ejects the processing liquid toward the substrate to store the processing liquid in the immersion bath.

In a preferred embodiment, the processing liquid supplying portion ejects the processing liquid toward the upper surface and a lower surface of the substrate to store the processing liquid in the immersion bath.

In a preferred embodiment, the processing liquid supplying portion ejects the processing liquid toward the substrate and stores the processing liquid in the immersion bath in a state in which the substrate holding portion rotates the substrate.

In a preferred embodiment, the substrate processing apparatus includes a liquid discharge portion. The liquid discharge portion is connected to a lower portion of the immersion bath and drains the processing liquid in the immersion bath. When the liquid discharge portion drains the processing liquid in the immersion bath, the processing liquid supplying portion ejects the processing liquid toward the substrate.

In a preferred embodiment, the substrate processing apparatus further includes a processing liquid cup. The processing liquid cup is provided around a periphery of the immersion bath. The processing liquid includes a rinse liquid. The processing liquid supplying portion supplies the rinse liquid to the immersion bath in a state in which the rinse liquid is stored in the immersion bath, and causes the rinse liquid to overflow from the immersion bath.

In a preferred embodiment, the substrate processing apparatus further includes a brush. The brush is disposed in the immersion bath. The immersion bath includes a bottom wall and a side wall extending upward from a peripheral edge portion of the bottom wall. The brush is disposed on an upper surface of the bottom wall. The brush comes into contact with the lower surface of the substrate and cleans the lower surface of the substrate in a state in which the substrate is immersed in the processing liquid stored in the immersion bath.

In a preferred embodiment, the substrate holding portion rotates the substrate in a state in which the lower surface of the substrate is in contact with the brush.

In a preferred embodiment, a processing liquid cup, a gas discharge portion, and a lid are further provided. The processing liquid cup is provided around a periphery of the immersion bath. The processing liquid cup has an inner circumferential edge that forms an opening through which the substrate is able to pass. The gas discharge portion discharges a gas in the processing liquid cup. The lid covers the inner circumferential edge.

In a preferred embodiment, the lid is provided on the substrate holding portion.

In a preferred embodiment, the substrate processing apparatus further includes a lid moving mechanism that moves the lid separately from the substrate holding portion.

In a preferred embodiment, the moving mechanism switches the state of the substrate from the non-immersion state to the immersion state by moving the substrate holding portion or the immersion bath in a state in which the processing liquid is stored in the immersion bath.

In a embodiment, preferred the substrate processing apparatus further includes a physical tool that is disposed inside the immersion bath and applies a physical force to the lower surface of the substrate held by the substrate holding portion, and a horizontal actuator that horizontally moves the physical tool inside the immersion bath.

In a preferred embodiment, the physical tool includes at least one of a scan nozzle that ejects the processing liquid toward the lower surface of the substrate held by the substrate holding portion, a cavitation nozzle that generates cavitation in the processing liquid in the immersion bath by ejecting the processing liquid containing bubbles in the processing liquid in the immersion bath, a brush that comes into contact with the lower surface of the substrate held by the substrate holding portion, an ultrasonic vibrator that generates ultrasonic vibration in the processing liquid in the immersion bath, and a polishing tool that comes into contact with an outer circumferential portion of the substrate held by the substrate holding portion.

In a preferred embodiment, the moving mechanism includes a posture changing actuator that changes a posture of the substrate between a horizontal posture in which the substrate is horizontal and an inclined posture in which the substrate is inclined with respect to a horizontal plane by rotating the substrate held by the substrate holding portion around a horizontal straight line, and the immersion state includes a partial immersion state in which the substrate is located inside the immersion bath and only a portion of the outer circumferential portion of the substrate is immersed in the processing liquid.

According to another aspect of the present invention, a substrate processing method includes rotatably holding a substrate, relatively moving the substrate and an immersion bath by a moving mechanism, storing a processing liquid in the immersion bath, and immersing the substrate in the immersion bath. When relatively moving the substrate and an immersion bath, the moving mechanism switches a state of the substrate between a non-immersion state in which the substrate is located outside the immersion bath and an immersion state in which the substrate is located inside the immersion bath and immersed in the processing liquid by moving the substrate or the immersion bath.

In a preferred embodiment, when storing the processing liquid in the immersion bath, the processing liquid is stored in the immersion bath by ejecting the processing liquid toward the substrate.

In a preferred embodiment, in the storing step, the processing liquid is stored in the immersion bath by ejecting the processing liquid toward an upper surface and a lower surface of the substrate.

In a preferred embodiment, in the storing step, the processing liquid is stored in the immersion bath by ejecting the processing liquid toward the substrate in a state in which the substrate is being rotated.

In a preferred embodiment, the substrate processing method further includes a step of discharging the processing liquid in the immersion bath out of the immersion bath. In the discharging step, the processing liquid is ejected toward the substrate.

In a preferred embodiment, a processing liquid cup is provided around a periphery of the immersion bath. The processing liquid includes a rinse liquid. In the immersion step, in a state in which the substrate is immersed in the rinse liquid stored in the immersion bath, the rinse liquid is supplied to the immersion bath, and the rinse liquid is caused to overflow from the immersion bath.

In a preferred embodiment, the substrate processing method further includes a step of cleaning the lower surface of the substrate with a brush. The immersion bath includes a bottom wall and a side wall extending upward from a peripheral edge portion of the bottom wall. The brush is disposed on an upper surface of the bottom wall. In the cleaning step, the brush comes into contact with the lower surface of the substrate to clean the lower surface of the substrate in a state in which the substrate is immersed in the processing liquid stored in the immersion bath.

In a preferred embodiment, a processing liquid cup is provided around a periphery of the immersion bath. The processing liquid cup has an inner circumferential edge that forms an opening through which the substrate is able to pass. In the immersion step, a lid is disposed to cover the inner circumferential edge.

In a preferred embodiment, in the moving step, the moving mechanism switches the state of the substrate from the non-immersion state to the immersion state by moving the substrate holding portion or the immersion bath in a state in which the processing liquid is stored in the immersion bath.

In a preferred embodiment, the substrate processing method further includes a step of horizontally moving a physical tool disposed inside the immersion bath and applying a physical force to the lower surface of the substrate inside the immersion bath.

In a preferred embodiment, the moving mechanism includes a posture changing actuator that changes a posture of the substrate between a horizontal posture in which the substrate is horizontal and an inclined posture in which the substrate is inclined with respect to a horizontal plane by rotating the substrate around a horizontal straight line, and in the moving step, the moving mechanism moves the substrate or the immersion bath to switch a state of the substrate between a non-immersion state in which the substrate is located outside the immersion bath and a partial immersion state in which the substrate is located inside the immersion bath and only a portion of an outer circumferential portion of the substrate is immersed in the processing liquid.

According to at least one aspect of the present invention, it is possible to provide a substrate processing apparatus and a substrate processing method capable of reducing the consumption amount of a processing liquid.

### BRIEF DESCRIPTION OF THE DRAWINGS

FIG. 1 is a schematic plan view of a substrate processing apparatus according to a first preferred embodiment.

FIG. 2 is a schematic view of a substrate processing unit in the substrate processing apparatus according to the first preferred embodiment.

FIG. 3 is a schematic view illustrating a structure around a substrate holding portion and a moving mechanism of the substrate processing apparatus according to the first preferred embodiment.

FIG. 4 is a block diagram of the substrate processing apparatus according to the first preferred embodiment.

FIG. 5 is a flowchart illustrating a substrate processing method according to the first preferred embodiment.

FIG. 6 is a schematic view for describing the substrate processing method according to the first preferred embodiment.

FIG. 7 is a schematic view for describing the substrate processing method according to the first preferred embodiment.

FIG. 8 is a schematic view for describing the substrate processing method according to the first preferred embodiment.

FIG. 9 is a schematic view for describing the substrate processing method according to the first preferred embodiment.

FIG. 10 is a schematic view for describing the substrate processing method according to the first preferred embodiment.

FIG. 11 is a schematic view for describing the substrate processing method according to the first preferred embodiment.

FIG. 12 is a schematic view for describing the substrate processing method according to the first preferred embodiment.

FIG. 13 is a schematic view for describing the substrate processing method according to the first preferred embodiment.

FIG. 14 is a schematic view for describing the substrate processing method according to the first preferred embodiment.

FIG. 15 is a schematic view for describing the substrate processing method according to the first preferred embodiment.

FIG. 16 is a schematic view for describing the substrate processing method according to the first preferred embodiment.

FIG. 17 is a schematic view for describing the substrate processing method according to the first preferred embodiment.

FIG. 18 is a flowchart illustrating a substrate processing method according to a second preferred embodiment.

FIG. 19 is a schematic view for describing the substrate processing method according to the second preferred embodiment.

FIG. 20 is a schematic view for describing the substrate processing method according to the second preferred embodiment.

FIG. 21 is a schematic view for describing the substrate processing method according to the second preferred embodiment.

FIG. 22 is a schematic view for describing the substrate processing method according to the second preferred embodiment.

FIG. 23 is a schematic view illustrating a substrate processing apparatus according to a first modification example.

FIG. 24 is a schematic view illustrating a substrate processing apparatus according to a second modification example.

FIG. 25 is a flowchart illustrating a substrate processing method according to the second modification example.

FIG. 26 is a schematic view illustrating a substrate processing apparatus according to a third modification example.

FIG. 27 is a schematic view illustrating a substrate processing apparatus according to a fourth modification example.

FIG. 28 is a schematic view illustrating a substrate processing apparatus according to a fifth modification example.

FIG. 29 is a schematic view illustrating a substrate processing apparatus according to a sixth modification example.

FIG. 30 is a schematic view illustrating a substrate processing apparatus according to a seventh modification example.

FIG. 31 is a schematic view illustrating a substrate processing apparatus according to an eighth modification example.

FIG. 32 is a schematic view illustrating a substrate processing apparatus according to a ninth modification example.

FIG. 33 is a schematic view illustrating the substrate processing apparatus according to the ninth modification example.

FIG. 34 is a schematic view illustrating the substrate processing apparatus according to the ninth modification example.

FIG. 35 is a schematic view illustrating a substrate processing apparatus according to a tenth modification example.

FIG. 36 is a schematic view illustrating a substrate processing apparatus according to an eleventh modification example.

FIG. 37 is a schematic view illustrating a substrate processing apparatus according to a twelfth modification example.

FIG. 38 is a schematic view illustrating the substrate processing apparatus according to the twelfth modification example.

FIG. 39 is a schematic view illustrating the substrate processing apparatus according to the twelfth modification example.

### DETAILED DESCRIPTION OF PREFERRED EMBODIMENTS

Hereinafter, preferred embodiments of a substrate processing apparatus according to the present invention will be described with reference to the drawings. Note that in the drawings, the same or corresponding portions are denoted by the same reference numerals, and the description thereof will not be repeated. In the present specification, an X axis, a Y axis, and a Z axis orthogonal to each other may be described in order to facilitate understanding of the invention. In the present preferred embodiment, the X axis and the Y axis are parallel to the horizontal direction, and the Z axis is parallel to the vertical direction. For easy understanding, a processing liquid may be hatched in the drawings.

### First Preferred Embodiment

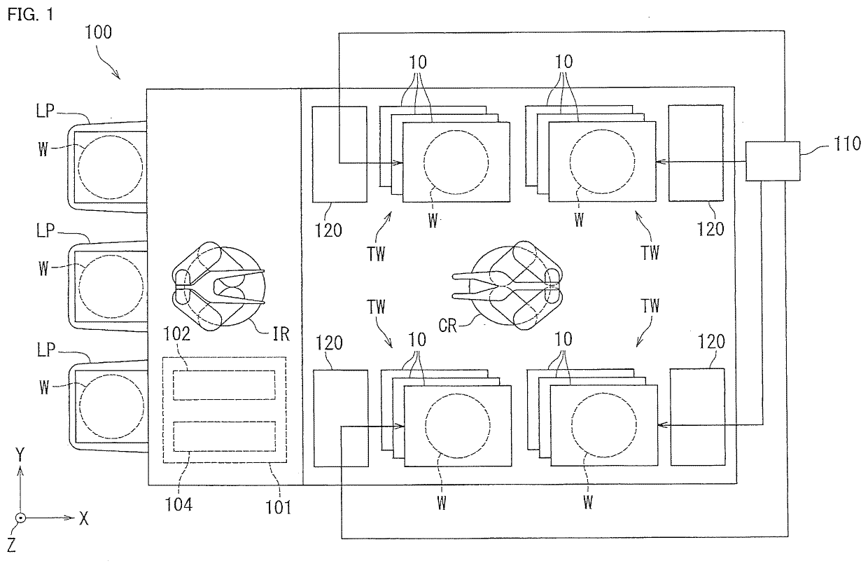

A substrate processing apparatus 100 according to a first preferred embodiment of the present invention will be described with reference to FIGS. 1 to 17. FIG. 1 is a schematic plan view of the substrate processing apparatus 100 according to the first preferred embodiment.

The substrate processing apparatus 100 processes a substrate W. The substrate processing apparatus 100 processes the substrate W to perform at least one of etching, surface processing, characteristics imparting, processing film formation, removal of at least a portion of the film, and cleaning on the substrate W.

The substrate W is used as a semiconductor substrate. The substrate W includes a semiconductor wafer. For example, the substrate W has a substantially disk shape. Here, the substrate processing apparatus 100 processes the substrates W one by one.

As illustrated in FIG. 1, the substrate processing apparatus 100 includes a plurality of substrate processing units 10, a processing liquid cabinet 110, a processing liquid box 120, a plurality of load ports LP, an indexer robot IR, a center robot CR, and a controller 101. The controller 101 controls the indexer robot IR and the center robot CR. The controller 101 includes a controlling portion 102 and a storage portion 104. The center robot CR is an example of a “transfer device” of the present invention.

Each of the load ports LP stacks and accommodates a plurality of substrates W. The indexer robot IR transfers the substrate W between the load port LP and the center robot CR. The center robot CR transfers the substrate W between the indexer robot IR and the substrate processing unit 10. Each of the substrate processing units 10 ejects a processing liquid onto the substrate W to process the substrate W. The processing liquid includes, for example, a chemical liquid, a rinse liquid, a removing liquid, and/or a water repellent. The processing liquid cabinet 110 stores a processing liquid. The processing liquid cabinet 110 may store a gas.

Specifically, the plurality of substrate processing units 10 form a plurality of towers TW (four towers TW in FIG. 1) disposed to surround the center robot CR in plan view. Each tower TW includes the plurality of substrate processing units 10 (three substrate processing units 10 in FIG. 1) stacked one above the other. The processing liquid boxes 120 respectively correspond to the plurality of towers TW. The liquid in the processing liquid cabinet 110 is supplied to all the substrate processing units 10 included in the tower TW corresponding to the processing liquid box 120 through any one of the processing liquid boxes 120. In addition, the gas in the processing liquid cabinet 110 is supplied to all the substrate processing units 10 included in the tower TW corresponding to the processing liquid box 120 through any one of the processing liquid boxes 120. In addition, the processing liquid cabinet 110 has a pump, a nozzle, and/or a filter for circulating the processing liquid.

The controller 101 controls various operations of the substrate processing apparatus 100. The controller 101 causes the substrate processing unit 10 to process the substrate W.

The controller 101 includes a controlling portion 102 and a storage portion 104. The controlling portion 102 includes a processor. The controlling portion 102 includes, for example, a central processing unit (CPU). Alternatively, the controlling portion 102 may include a general-purpose computing device.

The storage portion 104 stores data and a computer program. The data includes recipe data. The recipe data includes information indicating a plurality of recipes. Each of the plurality of recipes defines processing content and processing procedures of the substrate W. The controlling portion 102 executes the computer program stored in the storage portion 104 to execute a substrate processing operation.

The storage portion 104 includes a main storage device and an auxiliary storage device. The main storage device is, for example, a semiconductor memory. The auxiliary storage device is, for example, a semiconductor memory and/or a hard disk drive. The storage portion 104 may include a removable medium. The controlling portion 102 executes the computer program stored in the storage portion 104 to execute the substrate processing operation.

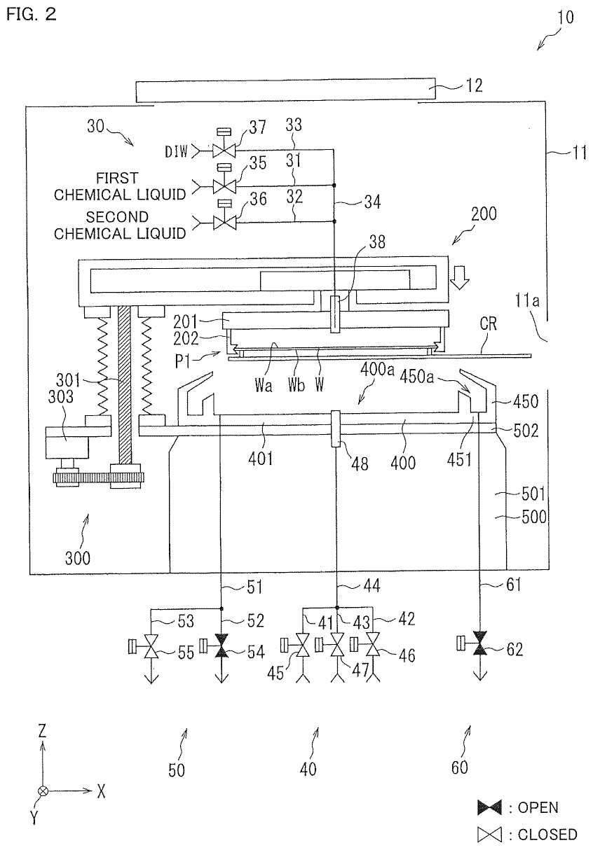

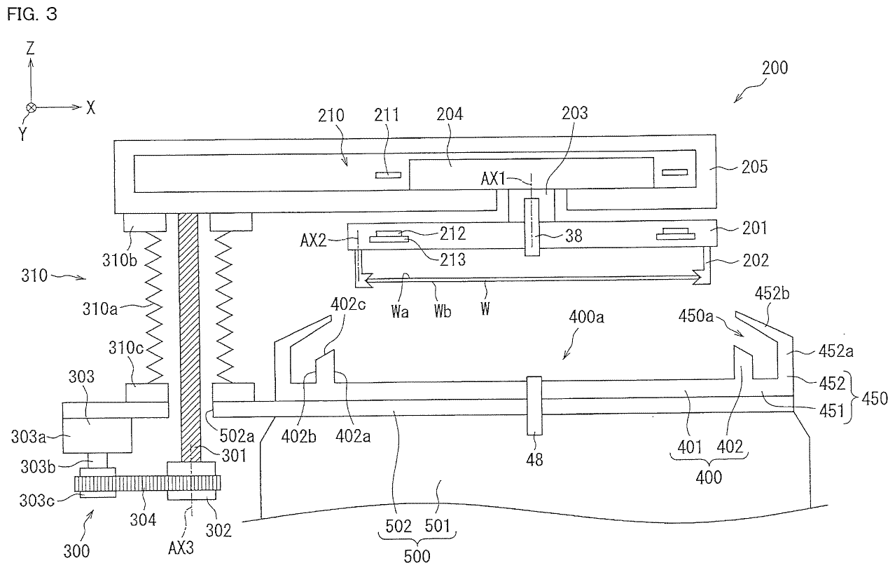

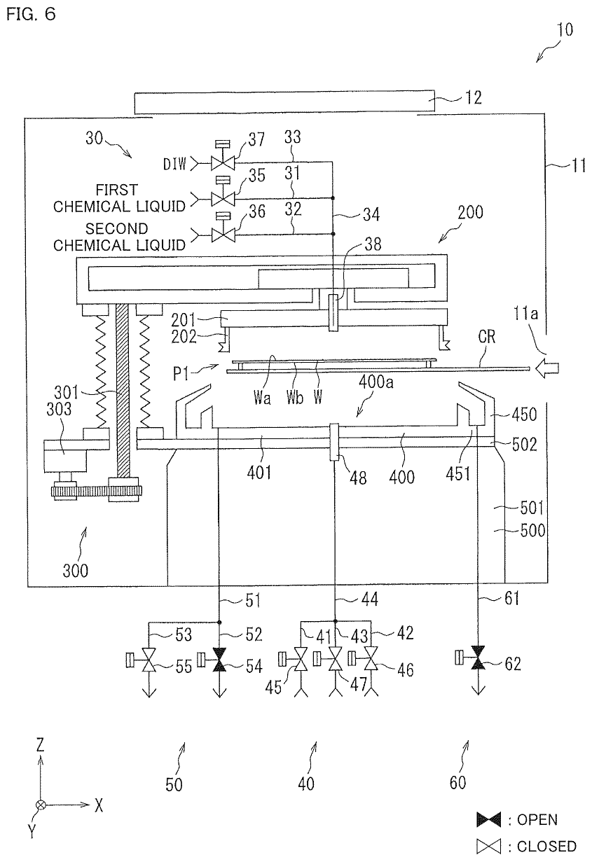

Next, the substrate processing unit 10 in the substrate processing apparatus 100 according to the first preferred embodiment will be described with reference to FIGS. 2 and 3. FIG. 2 is a schematic view of the substrate processing unit 10 in the substrate processing apparatus 100 according to the first preferred embodiment. FIG. 3 is a schematic view illustrating a structure around a substrate holding portion 200 and a moving mechanism 300 of the substrate processing apparatus 100 according to the first preferred embodiment. In FIG. 2, and FIGS. 6 to 17, 19 to 24, and 26 to 30, which will be described later, a first chemical liquid piping 31, a second chemical liquid piping 32, a rinse liquid piping 33, a common piping 34, an opening/closing valve 35, an opening/closing valve 36, and an opening/closing valve 37 of a first supplying portion 30 are drawn inside a chamber 11 due to the limitation of the drawing size, but a portion of the first chemical liquid piping 31, the second chemical liquid piping 32, the rinse liquid piping 33 and the common piping 34, the opening/closing valve 35, the opening/closing valve 36, and the opening/closing valve 37 are disposed outside the chamber 11.

As illustrated in FIG. 2, the substrate processing unit 10 includes the chamber 11, an air blowing unit 12, the substrate holding portion 200, the moving mechanism 300, an immersion bath 400, a cup 450, and an immersion bath supporting portion 500. The cup 450 is an example of a “processing liquid cup” of the present invention.

The chamber 11 has a substantially box shape having an internal space. The chamber 11 accommodates the substrates W. Here, the substrate processing apparatus 100 is of a single substrate processing type that processes the substrates W one by one, and the chamber 11 accommodates the substrates W one by one. The substrate W is accommodated in the chamber 11 and processed in the chamber 11. The chamber 11 accommodates the substrate holding portion 200, the moving mechanism 300, the immersion bath 400, and the immersion bath supporting portion 500. Further, an opening 11a through which the substrate W is carried in and out by the center robot CR is formed at a predetermined position on the side wall of the chamber 11.

The air blowing unit 12 is disposed on the upper portion of or above the chamber 11. For example, the air blowing unit 12 is disposed on the top surface of the chamber 11. The air blowing unit 12 sends air into the chamber 11. The air blowing unit 12 includes, for example, a fan filter unit (FFU). A downflow (downward flow) is formed in the chamber 11 by the air blowing unit 12 and an exhaust device (not illustrated).

As illustrated in FIG. 2, the substrate holding portion 200 holds the substrate W. The substrate holding portion 200 horizontally holds the substrate W so that an upper surface (front surface) Wa of the substrate W faces surface (rear surface) Wb of the upward and a lower substrate W faces vertically downward. The substrate holding portion 200 rotates the substrate W while holding the substrate W. For example, a laminated structure in which a recess is formed is provided on the upper surface Wa of the substrate W. The detailed structure of the substrate holding portion 200 will be described later.

The moving mechanism 300 moves the substrate holding portion 200. Specifically, the moving mechanism 300 moves the substrate holding portion 200 in the vertical direction. That is, the moving mechanism 300 lifts and lowers the substrate holding portion 200. The moving mechanism 300 includes, for example, a ball screw mechanism and an electric motor that applies a driving force to the ball screw mechanism. A detailed structure of the moving mechanism 300 will be described later.

The immersion bath 400 stores a processing liquid. Specifically, the immersion bath 400 has a container shape with an open upper surface, and the processing liquid is stored in an inner space 400a of the immersion bath 400. In addition, the immersion bath 400 accommodates the substrate W. As will be described later, the substrate W is immersed in the processing liquid stored in the immersion bath 400. As a result, the substrate W is processed with the processing liquid.

The immersion bath 400 has, for example, a substantially circular shape in plan view. The immersion bath 400 may have a circular cylindrical shape with a bottom. The immersion bath 400 is supported in a horizontal posture by the immersion bath supporting portion 500. Note that the immersion bath 400 may be installed in a horizontal posture on the bottom surface (bottom wall) of the chamber 11. For example, the immersion bath 400 may be made of silicon carbide (SiC) or stainless steel. For example, the immersion bath 400 may be made of aluminum coated with a fluororesin. The fluororesin includes, for example, polytetrafluoroethylene (PTFE).

As illustrated in FIG. 3, the immersion bath 400 has a bottom wall 401 and a side wall 402. The bottom wall 401 may have a circular shape in plan view. The side wall 402 is connected to the bottom wall 401. The side wall 402 may be connected to an end portion (peripheral edge portion) of the bottom wall 401. The side wall 402 extends upward from the bottom wall 401. The inner space 400a of the immersion bath 400 is defined by the bottom wall 401 and the side wall 402. In other words, the inner space 400a is a space surrounded by the bottom wall 401 and the side wall 402.

More specifically, the side wall 402 has an inner peripheral surface 402a, an outer peripheral surface 402b, and an upper surface 402c. The inner peripheral surface 402a defines the inner space 400a. The outer peripheral surface 402b is disposed outside the inner peripheral surface 402a. The upper surface 402c connects the upper end of the inner peripheral surface 402a and the upper end of the outer peripheral surface 402b. The upper surface 402c is inclined downward toward the outside.

The cup 450 is disposed around the periphery of the immersion bath 400. In the present preferred embodiment, the cup 450 and the immersion bath 400 are integrally formed. In other words, the cup 450 and the immersion bath 400 are a single member.

The cup 450 is disposed outside the side wall 402 of the immersion bath 400 at a predetermined distance from the side wall 402. Specifically, the cup 450 has a bottom wall 451 and a side wall 452. The bottom wall 451 is connected to the bottom wall 401 or the side wall 402 of the immersion bath 400. The side wall 452 is connected to a peripheral edge portion of the bottom wall 451. The side wall 452 has a lower wall portion 452a and an upper wall portion 452b. The lower wall portion 452a extends upward from the bottom wall 451. The upper wall portion 452b is inclined inward and upward from the upper end of the lower wall portion 452a. The bottom wall 451 and the side wall 452 of the cup 450 and the side wall 402 of the immersion bath 400 define an inner space 450a of the cup 450.

For example, the cup 450 collects the processing liquid that is scattered around the periphery of the substrate W due to the rotation of the substrate W. An exhaust device (not illustrated) may be connected to the cup 450, and a gas in the inner space 450a may be exhausted out of the chamber 11.

The immersion bath supporting portion 500 supports the immersion bath 400. In the present preferred embodiment, the immersion bath supporting portion 500 supports the immersion bath 400 and the cup 450. The immersion bath supporting portion 500 includes a housing 501 and a support plate 502. The housing 501 has an internal space and accommodates at least a portion of a second supplying portion 40, a first discharge portion 50, a second discharge portion 60, etc., that will be described later. The housing 501 is installed on the bottom surface (bottom wall) of the chamber 11. The support plate 502 is disposed on the upper portion of the housing 501. The support plate 502 has a plate shape and is supported by the housing 501 in a horizontal posture. The support plate 502 supports the immersion bath 400 in a horizontal posture. The support plate 502 protrudes in the horizontal direction from the housing 501. A through hole 502a penetrating the support plate 502 in the thickness direction is formed in a portion of the support plate 502 protruding in the horizontal direction from the housing 501. A screw shaft 301 that will be described later of the moving mechanism 300 is inserted into the through hole 502a.

As illustrated in FIG. 2, the substrate processing apparatus 100 includes the first supplying portion 30, the second supplying portion 40, the first discharge portion 50, and the second discharge portion 60. Note that the first supplying portion 30 and the second supplying portion 40 are examples of a “processing liquid supplying portion” of the present invention. The first discharge portion 50 is an example of a “liquid discharge portion” of the present invention.

The first supplying portion 30 supplies the processing liquid to the immersion bath 400. The first supplying portion 30 supplies the processing liquid from above the immersion bath 400. In the present preferred embodiment, the first supplying portion 30 supplies the processing liquid to the immersion bath 400 by ejecting the processing liquid toward the upper surface Wa of the substrate W held by the substrate holding portion 200.

Specifically, the first supplying portion 30 includes the first chemical liquid piping 31, the second chemical liquid piping 32, the rinse liquid piping 33, the common piping 34, the opening/closing valve 35, the opening/closing valve 36, the opening/closing valve 37, and a nozzle 38. The nozzle 38 is an example of an “upper nozzle” of the present invention.

The first chemical liquid piping 31, the second chemical liquid piping 32, the rinse liquid piping 33, and the common piping 34 are tubular members, and allow the processing liquid to flow therethrough.

A first chemical liquid is supplied from a supply source to the first chemical liquid piping 31. A downstream end of the first chemical liquid piping 31 is connected to the common piping 34. The opening/closing valve 35 is provided in the first chemical liquid piping 31 and opens and closes a flow path in the first chemical liquid piping 31. The opening/closing valve 35 adjusts the opening degree of the first chemical liquid piping 31 to adjust a flow rate of the first chemical liquid supplied to the first chemical liquid piping 31.

The first chemical liquid is not particularly limited, and includes, for example, a phosphoric acid, an SPM (sulfuric acid hydrogen peroxide water mixed solution), or ozone water. The SPM is a sulfuric acid hydrogen peroxide water mixed solution in which a sulfuric acid and hydrogen peroxide water are mixed. In the present preferred embodiment, the first chemical liquid is a phosphoric acid. Note that the first chemical liquid may be, for example, SC1 (a mixed solution of ammonia water, hydrogen peroxide water, and water) or an organic solvent.

A second chemical liquid is supplied from a supply source to the second chemical liquid piping 32. The downstream end of the second chemical liquid piping 32 is connected to the common piping 34. The opening/closing valve 36 is provided in the second chemical liquid piping 32 and opens and closes a flow path in the second chemical liquid piping 32. The opening/closing valve 36 adjusts the opening degree of the second chemical liquid piping 32 to adjust a flow rate of the second chemical liquid supplied to the second chemical liquid piping 32.

The second chemical liquid is not particularly limited, and includes, for example, a phosphoric acid, an SPM (sulfuric acid hydrogen peroxide water mixed solution), or ozone water. In the present preferred embodiment, the second chemical liquid is a phosphoric acid having a concentration different from that of the first chemical liquid. Note that the second chemical liquid may be, for example, SC1 (a mixed solution of ammonia water, hydrogen peroxide water, and water) or an organic solvent.

A rinse liquid is supplied from a supply source to the rinse liquid piping 33. The downstream end of the rinse liquid piping 33 is connected to the common piping 34. The opening/closing valve 37 is provided in the rinse liquid piping 33, and opens and closes a flow path in the rinse liquid piping 33. The opening/closing valve 37 adjusts the opening degree of the rinse liquid piping 33 to adjust a flow rate of the rinse liquid supplied to the rinse liquid piping 33.

Examples of the rinse liquid include deionized water (DIW), carbonated water, electrolyzed ion water, ozone water, ammonia water, hydrochloric acid water having a dilution concentration (for example, about 10 ppm to 100 ppm), or reduced water (hydrogen water). In the present preferred embodiment, the rinse liquid is deionized water (DIW).

Each of the opening/closing valve 35 to the opening/closing valve 37 includes a valve body (not illustrated) inside which a valve seat is provided, a valve element that opens and closes the valve seat, and an actuator (not illustrated) that moves the valve element between an open position and a closed position.

The downstream end of the common piping 34 is connected to the nozzle 38. The common piping 34 allows the processing liquid to flow through the nozzle 38.

The nozzle 38 ejects the processing liquid. In the present preferred embodiment, the nozzle 38 ejects the processing liquid toward the upper surface Wa of the substrate W held by the substrate holding portion 200. Note that the nozzle 38 may also eject the processing liquid to the immersion bath 400 in a state in which the substrate holding portion 200 does not hold the substrate W. The nozzle 38 is provided in a spin base 201 that will be described later of the substrate holding portion 200. The nozzle 38 is disposed, for example, at the central portion of the spin base 201. In the present preferred embodiment, the nozzle 38 is disposed on a rotational axis AX1 of the spin base 201. The nozzle 38 may be formed separately from the spin base 201, or may be formed by a portion of the spin base 201. In a case where the nozzle 38 is formed separately from the spin base 201, for example, a through hole extending in the up-down direction may be formed at the central portion of the spin base 201, and the nozzle 38 may be disposed in the through hole of the spin base 201. In this case, the nozzle 38 may be fixed to a housing 205.

The second supplying portion 40 supplies the processing liquid to the immersion bath 400. The second supplying portion 40 supplies the processing liquid from below the immersion bath 400. In the present preferred embodiment, the second supplying portion 40 supplies the processing liquid to the immersion bath 400 by ejecting the processing liquid toward the lower surface Wb of the substrate W held by the substrate holding portion 200.

Specifically, the second supplying portion 40 includes a first chemical liquid piping 41, a second chemical liquid piping 42, a rinse liquid piping 43, a common piping 44, an opening/closing valve 45, an opening/closing valve 46, an opening/closing valve 47, and a nozzle 48.

The first chemical liquid piping 41, the second chemical liquid piping 42, the rinse liquid piping 43, and the common piping 44 are annular members, and allow the processing liquid to flow therethrough.

The first chemical liquid is supplied from a supply source to the first chemical liquid piping 41. The downstream end of the first chemical liquid piping 41 is connected to the common piping 44. The opening/closing valve 45 is provided in the first chemical liquid piping 41 and opens and closes a flow path in the first chemical liquid piping 41. The opening/closing valve 45 adjusts the opening degree of the first chemical liquid piping 41 to adjust a flow rate of the first chemical liquid supplied to the first chemical liquid piping 41.

The second chemical liquid is supplied from a supply source to the second chemical liquid piping 42. The downstream end of the second chemical liquid piping 42 is connected to the common piping 44. The opening/closing valve 46 is provided in the second chemical liquid piping 42 and opens and closes a flow path in the second chemical liquid piping 42. The opening/closing valve 46 adjusts the opening degree of the second chemical liquid piping 42 to adjust a flow rate of the second chemical liquid supplied to the second chemical liquid piping 42.

The rinse liquid is supplied from a supply source to the rinse liquid piping 43. The downstream end of the rinse liquid piping 43 is connected to the common piping 44. The opening/closing valve 47 is provided in the rinse liquid piping 43, and opens and closes a flow path in the rinse liquid piping 43. The opening/closing valve 47 adjusts the opening degree of the rinse liquid piping 43 to adjust a flow rate of the rinse liquid supplied to the rinse liquid piping 43.

Each of the opening/closing valve 45 to the opening/closing valve 47 includes a valve body (not illustrated) inside which a valve seat is provided, a valve element that opens and closes the valve seat, and an actuator (not illustrated) that moves the valve element between an open position and a closed position.

The downstream end of the common piping 44 is connected to the nozzle 48. The common piping 44 allows the processing liquid to flow through the nozzle 48.

The nozzle 48 ejects the processing liquid. In the present preferred embodiment, the nozzle 48 ejects the processing liquid toward the lower surface Wb of the substrate W held by the substrate holding portion 200. Note that the nozzle 48 may also eject the processing liquid to the immersion bath 400 in a state in which the substrate holding portion 200 does not hold the substrate W. The nozzle 48 is disposed at the center of the immersion bath 400 of the substrate holding portion 200. The tip (upper end) of the nozzle 48 protrudes upward from the upper surface of the bottom wall 401 of the immersion bath 400. The nozzle 48 may be formed separately from the immersion bath 400, or may be formed by a portion of the immersion bath 400.

The first discharge portion 50 discharges the processing liquid stored in the immersion bath 400 out of the immersion bath 400. In the present preferred embodiment, the first discharge portion 50 discharges the processing liquid stored in the immersion bath 400 out of the chamber 11.

Specifically, the first discharge portion 50 includes a common piping 51, a drain piping 52, a return piping 53, an opening/closing valve 54, and an opening/closing valve 55. The common piping 51, the drain piping 52, and the return piping 53 are tubular members, and allow the processing liquid to flow therethrough.

An upstream end of the common piping 51 is connected to the bottom wall 401 of the immersion bath 400. The common piping 51 communicates with the inner space 400a of the immersion bath 400. The processing liquid in the immersion bath 400 flows into the common piping 51. The downstream end of the common piping 51 is connected to the drain piping 52 and the return piping 53.

The drain piping 52 drains the processing liquid from the common piping 51. For example, the drain piping 52 allows the processing liquid from the common piping 51 to flow through a drain tank (not illustrated). The opening/closing valve 54 is provided in the drain piping 52 and opens and closes a flow path in the drain piping 52.

The return piping 53 returns the processing liquid from the common piping 51 to the processing liquid cabinet 110. The processing liquid returned to the processing liquid cabinet 110 is reused. Therefore, since the amount of the processing liquid used can be decreased, the environmental load can be reduced. The opening/closing valve 55 is provided in the return piping 53 and opens and closes a flow path in the return piping 53.

Each of the opening/closing valve 54 and the opening/closing valve 55 includes a valve body (not illustrated) inside which a valve seat is provided, a valve element that opens and closes the valve seat, and an actuator (not illustrated) that moves the valve element between an open position and a closed position.

The second discharge portion 60 discharges the processing liquid in the cup 450 out of the cup 450. In the present preferred embodiment, the second discharge portion 60 discharges the processing liquid in the cup 450 out of the chamber 11.

Specifically, the second discharge portion 60 includes a drain piping 61 and an opening/closing valve 62. The drain piping 61 is a tubular member and allows the processing liquid to flow therethrough.

The drain piping 61 drains the processing liquid in the cup 450. Specifically, the upstream end of the drain piping 61 is connected to the bottom wall 451 of the cup 450. The drain piping 61 communicates with the inner space 450a of the cup 450. The processing liquid of the cup 450 flows into the drain piping 61. For example, the drain piping 61 allows the processing liquid to flow through a drain tank (not illustrated). The opening/closing valve 62 is provided in the drain piping 61 and opens and closes a flow path in the drain piping 61. The opening/closing valve 62 includes a valve body (not illustrated) inside which a valve seat is provided, a valve element that opens and closes the valve seat, and an actuator (not illustrated) that moves the valve element between an open position and a closed position.

Next, the substrate holding portion 200 and the moving mechanism 300 will be further described with reference to FIG. 3.

As illustrated in FIG. 3, the substrate holding portion 200 includes the spin base 201, a chuck pin 202, a shaft 203, an electric motor 204, and the housing 205. Note that the spin base 201 is an example of a “base” of the present invention.

The chuck pin 202 is provided on the spin base 201 disposed above the substrate W. The chuck pin 202 chucks the substrate W. Typically, the spin base 201 is provided with a plurality of chuck pins 202. The chuck pin 202 protrudes downward from a lower surface of the spin base 201. The chuck pin 202 has a pin-shaped portion extending in the up-down direction and a contact portion provided at the lower end of the pin-shaped portion and in contact with the circumferential edge of the substrate W. Each chuck pin 202 is rotatable about a rotational axis AX2 (a central axis of each pin-shaped portion) extending in the up-down direction. The chuck pin 202 rotates about the rotational axis AX2 between a holding position where the substrate W is held and a non-holding position where the substrate W is not held.

The shaft 203 is a hollow shaft. The shaft 203 extends in the vertical direction along the rotational axis AX1. The spin base 201 is coupled to the lower end of the shaft 203. The substrate W is located below the spin base 201.

The spin base 201 has a disk shape and horizontally supports the substrate W. The shaft 203 extends upward from a central portion of the spin base 201. The electric motor 204 applies a rotational force to the shaft 203. The electric motor 204 rotates the shaft 203 in the rotation direction to rotate the substrate W and the spin base 201 around the rotational axis AX1. The housing 205 has a substantially box shape and accommodates a portion of the shaft 203 and the electric motor 204. The electric motor 204 is attached to a predetermined position of the housing 205.

In addition, the substrate holding portion 200 includes a chuck driving mechanism 210 that rotates the plurality of chuck pins 202. The chuck driving mechanism 210 is configured by using a known technique (for example, Japanese Patent Application Publication No. 2016-25186), and will thus be briefly described.

The chuck driving mechanism 210 includes a driving magnet 211, a driven magnet 212, and a lifting/lowering plate 213. The driving magnet 211 is disposed in the housing 205. The driving magnet 211 is disposed over one turn to surround the rotational axis AX1. The driving magnet 211 is moved in the up-down direction with respect to the housing 205 by a lifting/lowering mechanism (not illustrated). The driven magnet 212 and the lifting/lowering plate 213 are disposed in the spin base 201. The driven magnet 212 is fixed to the lifting/lowering plate 213. The lifting/lowering plate 213 is biased upward by a biasing member (not illustrated). The driven magnet 212 and the lifting/lowering plate 213 are disposed over one turn to surround the rotational axis AX1. The driven magnet 212 is disposed at a position directly below the driving magnet 211. The lifting/lowering plate 213 is provided with a cam or a link mechanism that rotates the chuck pin 202 between the holding position and the non-holding position. When the driving magnet 211 is lifted and lowered, the driven magnet 212 and the lifting/lowering plate 213 are lifted and lowered. As a result, the chuck pin 202 is rotated between the holding position and the non-holding position, whereby the substrate W is held by the chuck pin 202 or released from the holding.

The moving mechanism 300 includes, for example, the screw shaft 301, a nut 302, an electric motor 303, and a driving belt 304.

The screw shaft 301 and the nut 302 configure a ball screw mechanism. The screw shaft 301 extends in the vertical direction. An upper end of the screw shaft 301 is fixed to the housing 205 of the substrate holding portion 200. A screw groove is formed on the outer peripheral surface of the screw shaft 301.

The nut 302 has a ball that contacts the screw groove of the screw shaft 301. Since the nut 302 rotates about a central axis AX3 of the screw shaft 301, the screw shaft 301 moves in the vertical direction.

The electric motor 303 includes, for example, a motor body 303a, a motor shaft 303b, and a motor pulley 303c. The motor body 303a is fixed to the support plate 502. The motor pulley 303c is fixed to the tip of the motor shaft 303b.

The driving belt 304 is stretched around outer peripheral surfaces of the motor pulley 303c and the nut 302. The driving belt 304 transmits the rotational force of the motor pulley 303c to the nut 302. As a result, when the motor pulley 303c is rotated, the nut 302 is rotated.

The screw shaft 301 is arranged not to move in the horizontal direction. The screw shaft 301 is arranged not to rotate about the central axis AX3.

In the moving mechanism 300, when the electric motor 303 is driven, the driving force of the electric motor 303 is transmitted to the nut 302 through the driving belt 304. The nut 302 is then rotated, whereby the screw shaft 301 is lifted and lowered in the vertical direction. The moving mechanism 300 may be arranged such that the screw shaft 301 is rotated about the central axis AX3.

The moving mechanism 300 includes a shaft cover 310. The shaft cover 310 includes a bellows portion 310a that can expand and contract in the vertical direction, an upper plate 310b that attaches an upper end of the bellows portion 310a to the housing 205 of the substrate holding portion 200, and a lower plate 310c that attaches a lower end of the bellows portion 310a to the support plate 502. Note that although a cover that covers the electric motor 303, the nut 302, etc., is not provided in the drawings, a cover that covers the electric motor 303, the nut 302, etc., may be provided. In addition, the electric motor 303, the nut 302, etc., may be covered with the housing 501 of the immersion bath supporting portion 500.

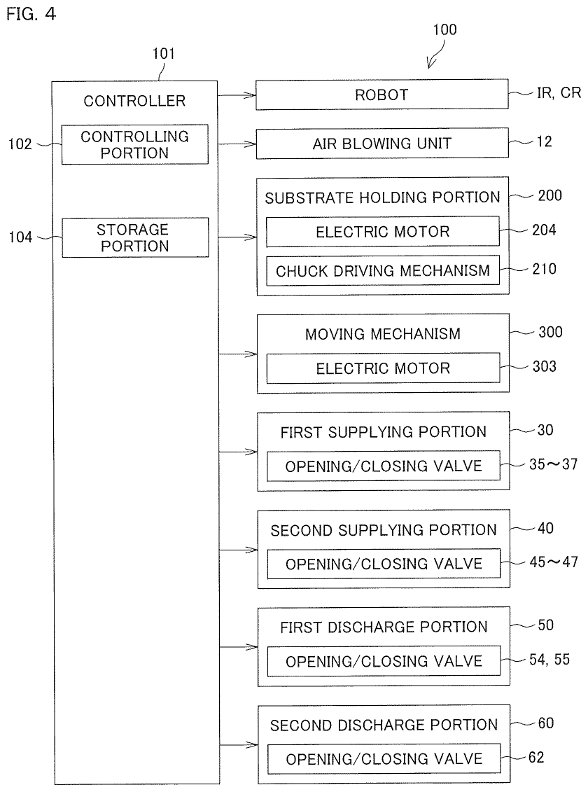

Next, the substrate processing apparatus 100 according to the first preferred embodiment will be described with reference to FIGS. 1 to 4. FIG. 4 is a block diagram of the substrate processing apparatus 100 according to the first preferred embodiment.

As illustrated in FIG. 4, the controller 101 controls various operations of the substrate processing apparatus 100. The controller 101 controls the indexer robot IR, the center robot CR, the air blowing unit 12, the substrate holding portion 200, the moving mechanism 300, the first supplying portion 30, the second supplying portion 40, the first discharge portion 50, and the second discharge portion 60. Specifically, the controller 101 controls the indexer robot IR, the center robot CR, the air blowing unit 12, the substrate holding portion 200, the moving mechanism 300, the first supplying portion 30, the second supplying portion 40, the first discharge portion 50, and the second discharge portion 60 by transmitting control signals to the indexer robot IR, the center robot CR, the air blowing unit 12, the substrate holding portion 200, the moving mechanism 300, the first supplying portion 30, the second supplying portion 40, the first discharge portion 50, and the second discharge portion 60.

The controlling portion 102 controls the indexer robot IR to deliver the substrate W by the indexer robot IR.

The controlling portion 102 controls the center robot CR to deliver the substrate W by the center robot CR. For example, the center robot CR receives the unprocessed substrate W and carries the substrate W into one of the plurality of chambers 11. In addition, the center robot CR receives the processed substrate W from the chamber 11 and carries out the substrate W.

The controlling portion 102 controls the air blowing unit 12 to send air into the chamber 11. For example, the controlling portion 102 controls the air blowing unit 12 and an exhaust device (not illustrated) to form a downflow in the chamber 11.

The controlling portion 102 controls the substrate holding portion 200 to control attachment/detachment of the substrate W, start of rotation of the substrate W, change of a rotational speed, and stop of rotation of the substrate W. For example, the controlling portion 102 can control the substrate holding portion 200 to change a rotational speed of the substrate holding portion 200. Specifically, the controlling portion 102 can change a rotational speed of the substrate W by changing a rotational speed of a spin motor 24 of the substrate holding portion 200.

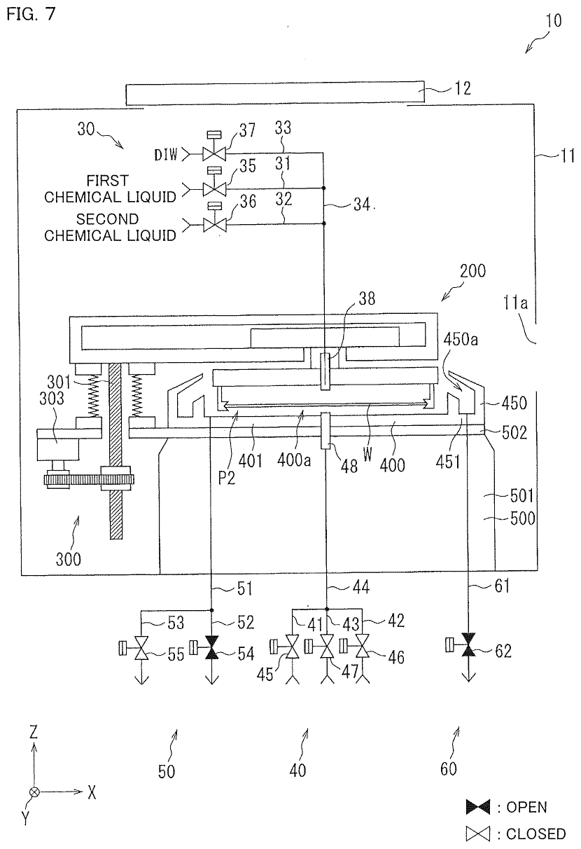

The controlling portion 102 controls the moving mechanism 300 to change a height position of the substrate holding portion 200. For example, the controlling portion 102 moves the substrate W between a first height position P1 (see FIG. 2) and a second height position P2 (see FIG. 7) by controlling the moving mechanism 300 to move the substrate holding portion 200. The first height position P1 is a height position of the substrate W when the substrate W is delivered between the center robot CR and the substrate holding portion 200. The second height position P2 is a height position of the substrate W when the substrate W is immersed in the processing liquid stored in the immersion bath 400. That is, the state in which the substrate W is disposed at the first height position P1 is a non-immersion state in which the substrate W is located outside the immersion bath 400. The state in which the substrate W is disposed at the second height position P2 is an immersion state in which the substrate W is located inside the immersion bath 400 and immersed in the processing liquid.

The controlling portion 102 can switch the state of the opening/closing valve 35 between an open state and a closed state by controlling the opening/closing valve 35 of the first supplying portion 30. Specifically, the controlling portion 102 can cause the first chemical liquid flowing in the first chemical liquid piping 31 to pass toward the nozzle 38 by controlling the opening/closing valve 35 of the first supplying portion 30 to open the opening/closing valve 35. In addition, the controlling portion 102 can stop the supply of the first chemical liquid flowing in the first chemical liquid piping 31 toward the nozzle 38 by controlling the opening/closing valve 35 of the first supplying portion 30 to close the opening/closing valve 35. Similarly, the controlling portion 102 can switch the states of the opening/closing valve 36 and the opening/closing valve 37 between the open state and the closed state by controlling the opening/closing valve 36 and the opening/closing valve 37 of the first supplying portion 30.

The controlling portion 102 can switch the state of the opening/closing valve 45 between the open state and the closed state by controlling the opening/closing valve 45 of the second supplying portion 40. Specifically, the controlling portion 102 can cause the first chemical liquid flowing in the first chemical liquid piping 41 to pass toward the nozzle 48 by controlling the opening/closing valve 45 of the second supplying portion 40 to open the opening/closing valve 45. In addition, the controlling portion 102 can stop the supply of the first chemical liquid flowing in the first chemical liquid piping 41 toward the nozzle 48 by controlling the opening/closing valve 45 of the second supplying portion 40 to close the opening/closing valve 45. Similarly, the controlling portion 102 can switch the states of the opening/closing valve 46 and the opening/closing valve 47 between the open state and the closed state by controlling the opening/closing valve 46 and the opening/closing valve 47 of the second supplying portion 40.

The controlling portion 102 can switch the state of the opening/closing valve 54 between the open state and the closed state by controlling the opening/closing valve 54 of the first discharge portion 50. Specifically, the controlling portion 102 can cause the processing liquid flowing in the drain piping 52 to pass by controlling the opening/closing valve 54 to open the opening/closing valve 54. In addition, the controlling portion 102 can stop the processing liquid flowing in the drain piping 52 from being drained by controlling the opening/closing valve 54 to close the opening/closing valve 54. Similarly, the controlling portion 102 can switch the state of the opening/closing valve 55 between the open state and the closed state by controlling the opening/closing valve 55 of the first discharge portion 50.

The controlling portion 102 can switch the state of the opening/closing valve 62 between the open state and the closed state by controlling the opening/closing valve 62 of the second discharge portion 60. Specifically, the controlling portion 102 can cause the processing liquid flowing in the drain piping 61 to pass by controlling the opening/closing valve 62 to open the opening/closing valve 62. In addition, the controlling portion 102 can stop the processing liquid flowing in the drain piping 61 from being drained by controlling the opening/closing valve 62 to close the opening/closing valve 62.

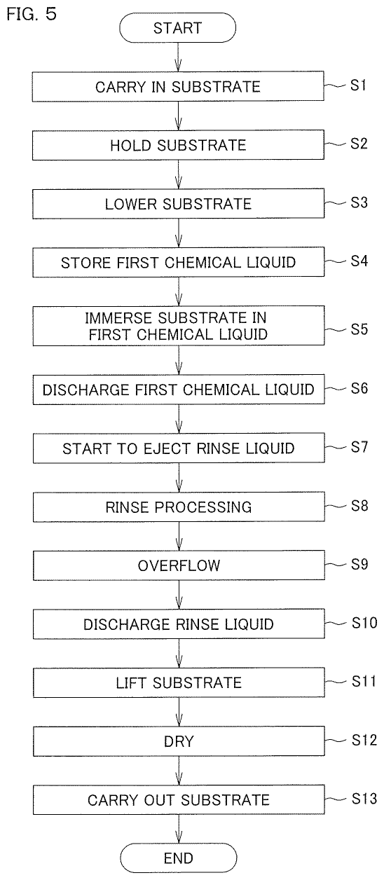

Next, a substrate processing method according to the first preferred embodiment will be described with reference to FIGS. 2 and 5 to 17. FIG. 5 is a flowchart illustrating a substrate processing method according to the first preferred embodiment. FIGS. 6 to 17 are schematic views for describing the substrate processing method according to the first preferred embodiment. The substrate processing method performed by the substrate processing apparatus 100 according to the first preferred embodiment includes steps S1 to S13. Steps S1 to S13 are executed by the controlling portion 102. Step S2 is an example of a “holding step” of the present invention. Step S3 is an example of a “moving step” of the present invention. Step S4 is an example of a “storing step” of the present invention. Steps S5 and S9 are examples of an “immersion step” of the present invention. Steps S6 and S10 are examples of a “discharging step” of the present invention.

As illustrated in FIG. 5, in step S1, the substrate W is carried into the chamber 11. Specifically, as illustrated in FIG. 6, the controlling portion 102 controls the center robot CR to carry the substrate W supported by the arm of the center robot CR into the chamber 11. At that time, the substrate holding portion 200 is retracted further upward than the height position at the time of delivering the substrate W. When step S1 is executed, the opening/closing valves 35 to 37, 45 to 47, and 55 are in a closed state, and the opening/closing valves 54 and 62 are in an open state.

Next, in step S2, the substrate W is held. Specifically, as illustrated in FIG. 2, the controlling portion 102 controls the moving mechanism 300 to move the substrate holding portion 200. Specifically, the controlling portion 102 controls the moving mechanism 300 to move (lower) the substrate holding portion 200 to a height position where the substrate W is delivered between the substrate holding portion 200 and the center robot CR.

The controlling portion 102 controls the substrate holding portion 200 such that the substrate W is held by the chuck pin 202. As a result, the substrate holding portion 200 rotatably holds the substrate W. At that time, the substrate W is located at the first height position P1. That is, the substrate W is in a non-immersion state of being located outside the immersion bath 400.

Next, in step S3, the substrate W is lowered. Specifically, the controlling portion 102 controls the center robot CR to move the arm of the center robot CR to the outside of the chamber 11.

As illustrated in FIG. 7, the controlling portion 102 controls the moving mechanism 300 to move (lower) the substrate holding portion 200, thereby moving (lowering) the substrate W from the first height position P1 to the second height position P2. As a result, the substrate W is disposed in the inner space 400a of the immersion bath 400.

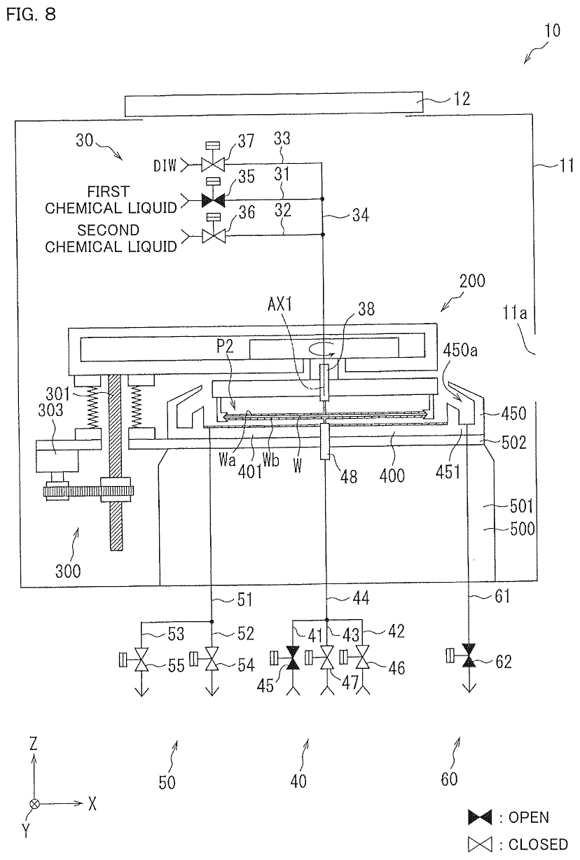

Next, in step S4, the first chemical liquid is stored in the immersion bath 400. Specifically, as illustrated in FIG. 8, the controlling portion 102 switches the opening/closing valve 54 from the open state to the closed state. In addition, the controlling portion 102 switches the opening/closing valve 35 and the opening/closing valve 45 from the closed state to the open state. As a result, the first chemical liquid is ejected from the nozzle 38 toward the upper surface Wa of the substrate W, and the first chemical liquid is ejected from the nozzle 48 toward the lower surface Wb of the substrate W.

At that time, the controlling portion 102 controls the substrate holding portion 200 to rotate the substrate W. Note that the rotational speed of the substrate W is not particularly limited, but is, for example, 100 rpm or more and 500 rpm or less.

The first chemical liquid flows down from the upper surface Wa and the lower surface Wb of the substrate W and is stored in the immersion bath 400.

In step S4, since the first chemical liquid is ejected to the substrate W while rotating the substrate W, the first chemical liquid wets and spreads immediately over the entire surface of the upper surface Wa and the lower surface Wb of the substrate W. Therefore, for example, it is possible to suppress a difference in processing time using the first chemical liquid between the central portion and the outer circumferential portion of the substrate W.

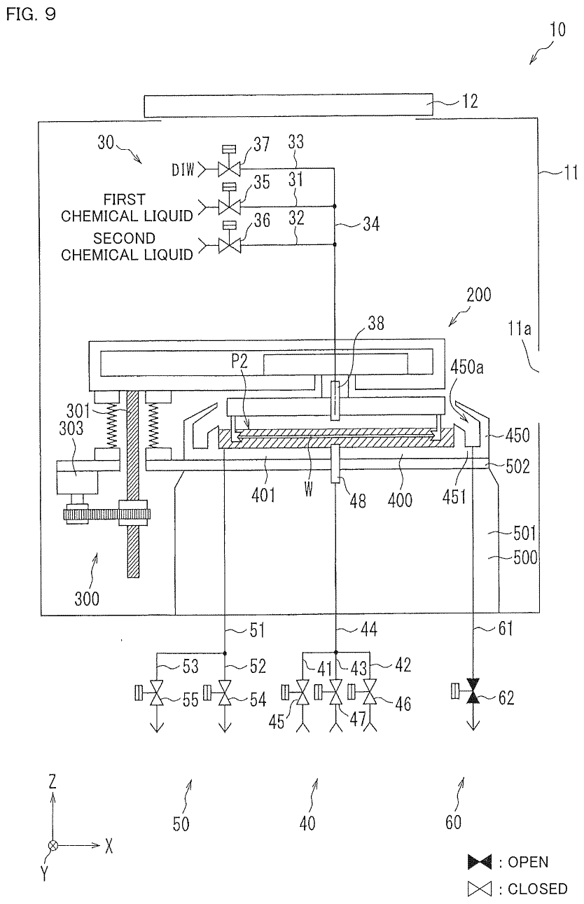

Next, in step S5, the substrate W is immersed in the first chemical liquid. Specifically, as illustrated in FIG. 9, the controlling portion 102 switches the opening/closing valve 35 and the opening/closing valve 45 from the open state to the closed state when a predetermined time has elapsed from the start of supply of the first chemical liquid. At that time, the liquid level of the first chemical liquid is higher than the upper surface Wa of the substrate W, and the substrate W is immersed in the first chemical liquid. That is, the substrate W is located inside the immersion bath 400 and is in an immersion state in which the substrate W is immersed in the processing liquid.

In addition, the controlling portion 102 controls the substrate holding portion 200 to stop the rotation of the substrate W. Note that the controlling portion 102 need not stop the rotation of the substrate W. That is, the controlling portion 102 may continue the rotation of the substrate W. In this case, a rotational speed of the substrate W is not particularly limited, but may be lower than the rotational speed in step S4. The rotational speed of the substrate W may be, for example, several tens rpm or more and several hundreds rpm or less.

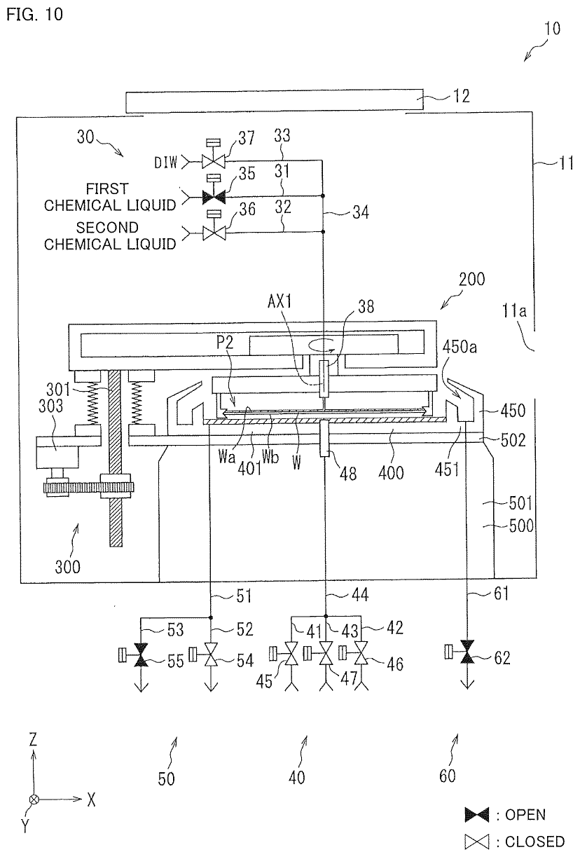

Next, in step S6, the first chemical liquid is discharged from the immersion bath 400. Specifically, as illustrated in FIG. 10, when a predetermined time has elapsed after switching the opening/closing valve 35 and the opening/closing valve 45 from the open state to the closed state, the controlling portion 102 switches the opening/closing valve 55 from the closed state to the open state. As a result, the first chemical liquid in the immersion bath 400 returns to the processing liquid cabinet 110. Note that in step S6, the controlling portion 102 may switch the opening/closing valve 54 from the closed state to the open state and drain the first chemical liquid.

In addition, when the first chemical liquid is discharged from the immersion bath 400, the controlling portion 102 switches the opening/closing valve 35 from the closed state to the open state. As a result, the first chemical liquid is ejected from the nozzle 38 to the upper surface Wa of the substrate W. Therefore, since the upper surface Wa of the substrate W can be suppressed from drying, it is possible to suppress collapse of the pattern and generation of particles. Note that the amount of the first chemical liquid ejected from the nozzle 38 is smaller than the amount of the first chemical liquid discharged from the first discharge portion 50.

At that time, the controlling portion 102 also controls the substrate holding portion 200 to rotate the substrate W. Note that the rotational speed of the substrate W is not particularly limited, but is, for example, 100 rpm or more and 500 rpm or less.

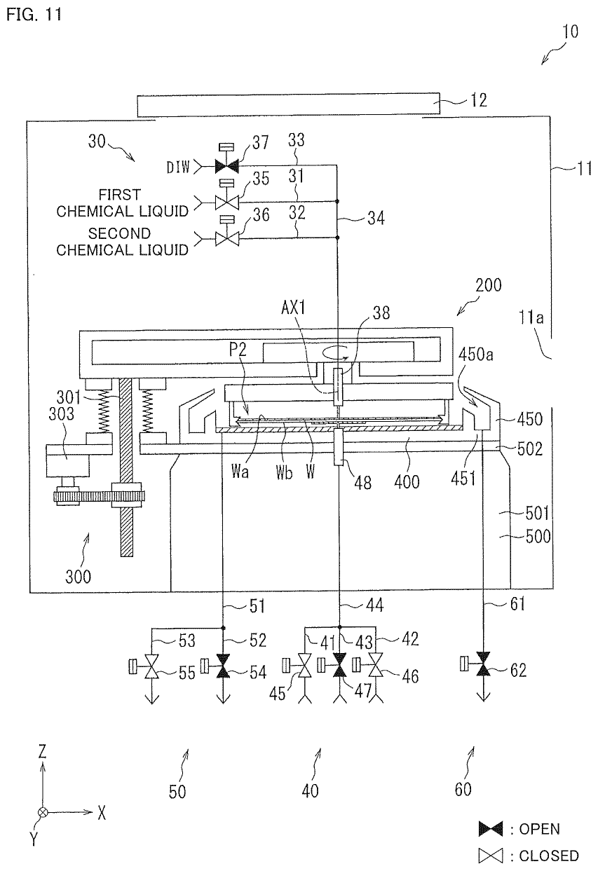

Next, in step S7, the ejection of the rinse liquid is started. Specifically, as illustrated in FIG. 11, the controlling portion 102 switches the opening/closing valve 54 from the closed state to the open state and switches the opening/closing valve 55 from the open state to the closed state when a predetermined time has elapsed from the start of discharge of the first chemical liquid. At that time, the controlling portion 102 switches the opening/closing valve 35 from the open state to the closed state, and switches the opening/closing valve 37 from the closed state to the open state. As a result, the processing liquid ejected onto the upper surface Wa of the substrate W is switched from the first chemical liquid to the rinse liquid. At that time, the controlling portion 102 also switches the opening/closing valve 47 from the closed state to the open state. As a result, the rinse liquid is ejected from the nozzle 48 to the lower surface Wb of the substrate W.

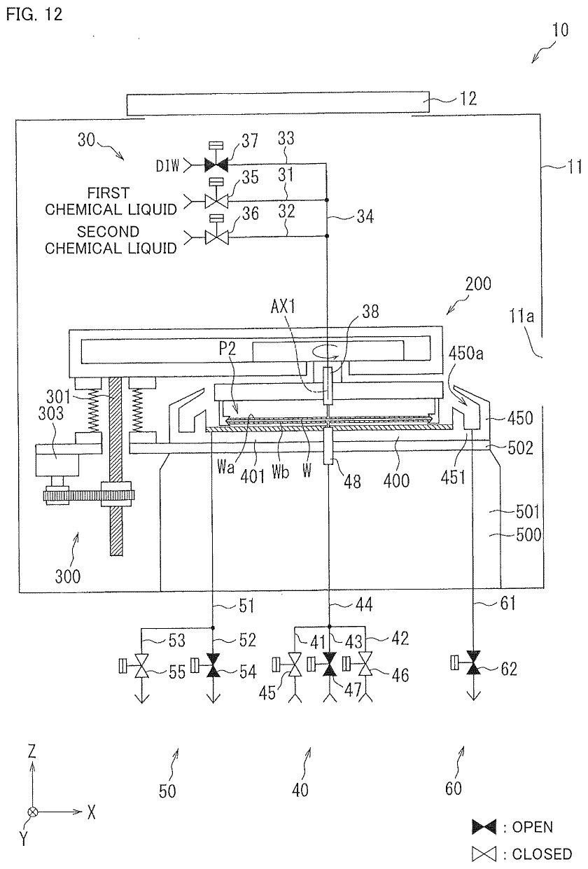

Next, in step S8, the substrate W is rinsed. Specifically, as illustrated in FIG. 12, the controlling portion 102 maintains the opening/closing valve 37, the opening/closing valve 47, and the opening/closing valve 54 in the open state. As a result, the upper surface Wa and the lower surface Wb of the substrate W are rinsed.

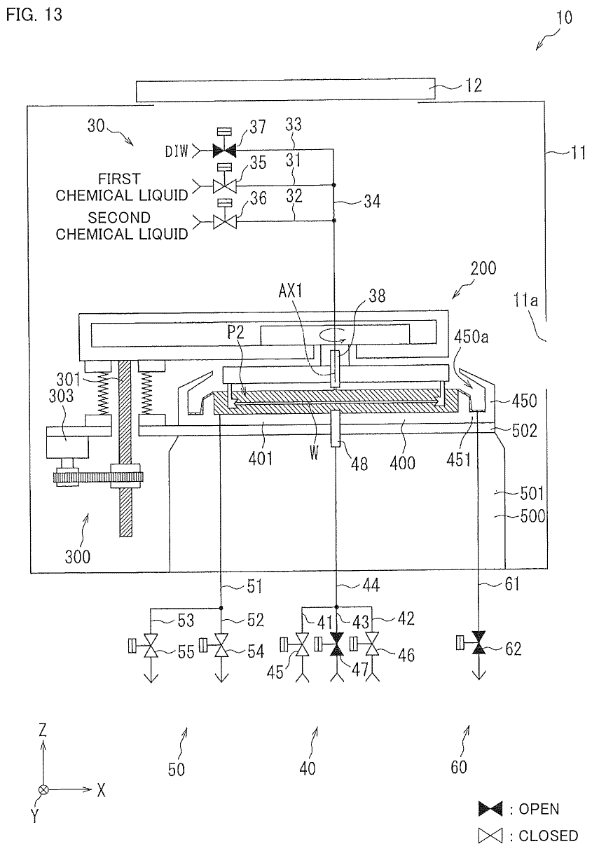

Next, in step S9, the rinse liquid is caused to overflow. Specifically, as illustrated in FIG. 13, the controlling portion 102 switches the opening/closing valve 54 from the open state to the closed state when a predetermined time has elapsed from the start of ejection of the rinse liquid in step S7. As a result, the rinse liquid is stored in the immersion bath 400, and the substrate W is immersed in the rinse liquid. The rinse liquid in the immersion bath 400 overflows after filling the inner space 400a of the immersion bath 400. That is, in a state in which the rinse liquid is stored in the immersion bath 400, the rinse liquid is supplied to the immersion bath 400, and the rinse liquid overflows from the immersion bath 400. As a result, the cup 450 is cleaned by the overflowed rinse liquid.

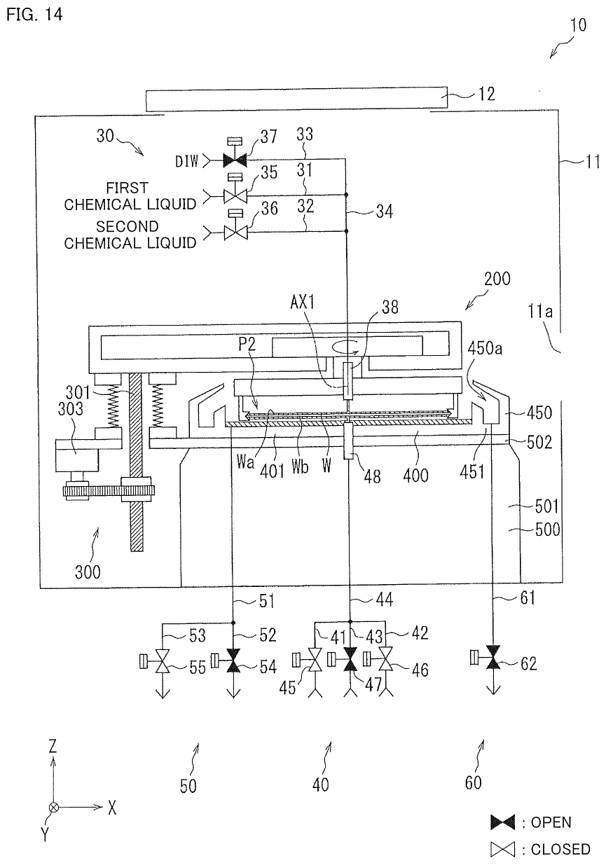

Next, in step S10, the rinse liquid is discharged from the immersion bath 400. Specifically, as illustrated in FIG. 14, when a predetermined time has elapsed after switching the opening/closing valve 54 from the open state to the closed state, the controlling portion 102 switches the opening/closing valve 54 from the closed state to the open state. As a result, the rinse liquid in the immersion bath 400 is drained.

In addition, the controlling portion 102 maintains the opening/closing valve 37 and the opening/closing valve 47 in the open state when the rinse liquid is discharged from the immersion bath 400. As a result, the rinse liquid is ejected from the nozzles 38 and 48 to the substrate W. In step S10, since the rinse liquid is ejected to the upper surface Wa and the lower surface Wb of the substrate W when the rinse liquid is discharged from the immersion bath 400, it is possible to suppress the upper surface Wa and the lower surface Wb of the substrate W from being dried. Therefore, generation of particles can be suppressed.

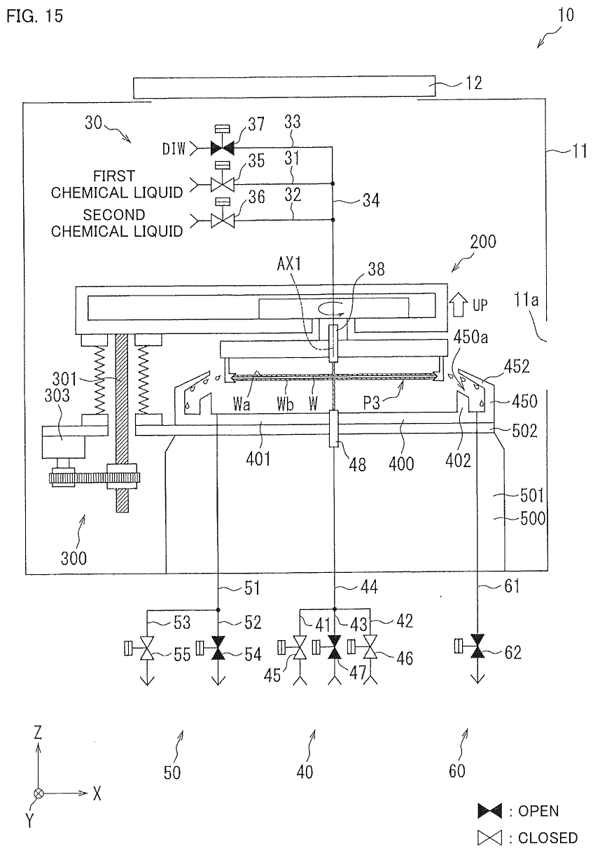

Next, in step S11, the substrate W is lifted. Specifically, as illustrated in FIG. 15, the controlling portion 102 moves the substrate holding portion 200 to a third height position P3 where the substrate W faces the side wall 452 of the cup 450 in the horizontal direction. The third height position P3 is lower than the first height position P1 and higher than the second height position P2. The substrate W is disposed at a height position between the upper end of the side wall 402 of the immersion bath 400 and the upper end (inner circumferential end) of the side wall 452 of the cup 450 in a state of being disposed at the third height position P3. That is, the side surface of the substrate W faces the inner space 450a.

Furthermore, for example, the controlling portion 102 may increase the rotational speed of the substrate W after lifting the substrate W to the third height position P3. The rotational speed of the substrate W is not particularly limited, but is, for example, 1500 rpm to 2000 rpm or more.

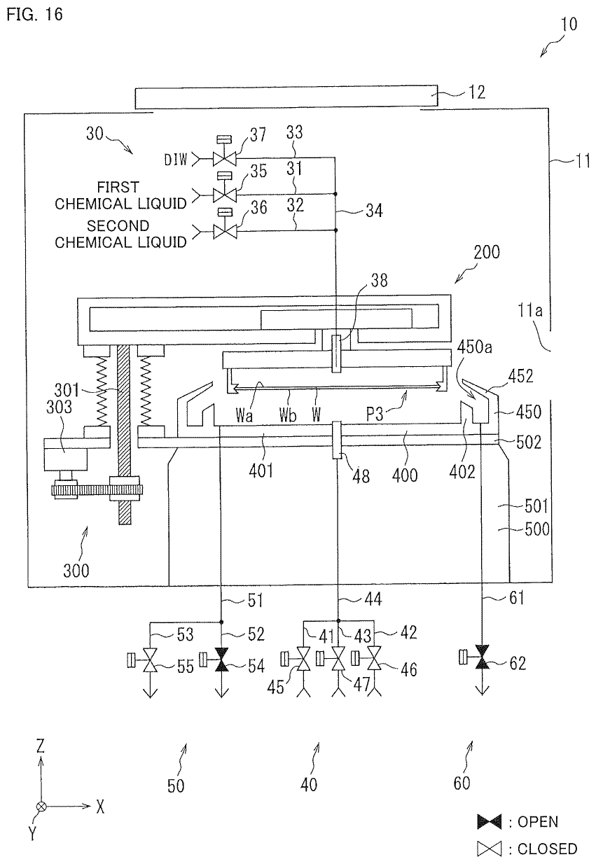

Next, in step S12, the substrate W is dried. Specifically, as illustrated in FIG. 16, the controlling portion 102 switches the opening/closing valve 37 and the opening/closing valve 47 from the open state to the closed state. As a result, the rinse liquid is not ejected to the substrate W, and the rinse liquid on the substrate W is blown off by the centrifugal force, and the substrate W is dried. Thereafter, the controlling portion 102 controls the substrate holding portion 200 to stop the rotation of the substrate W.

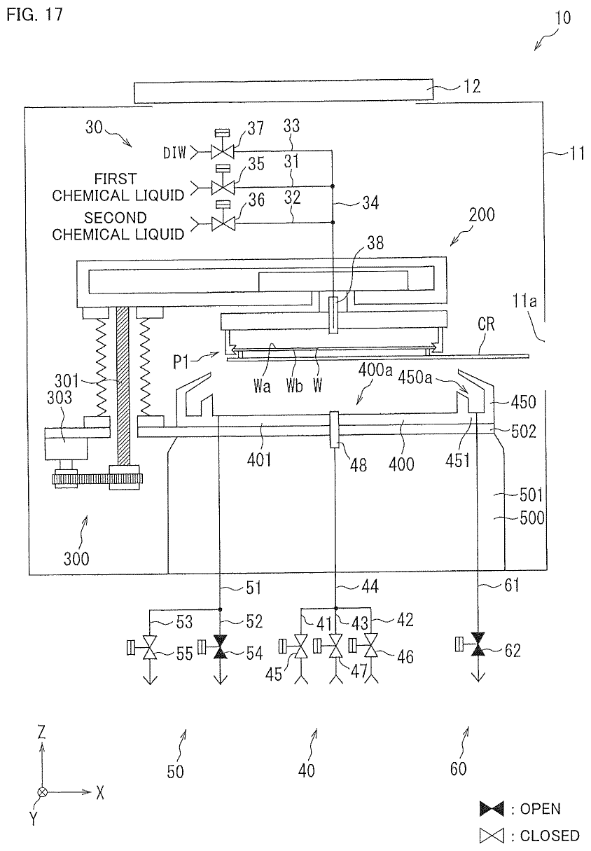

Next, in step S13, the substrate W is carried out of the chamber 11. Specifically, the controlling portion 102 controls the moving mechanism 300 to lift the substrate holding portion 200, retracts the substrate W to a position higher than the first height position P1, and then controls the center robot CR to insert the arm of the center robot CR into the chamber 11. The controlling portion 102 then controls the moving mechanism 300 to lower the substrate holding portion 200 and lowers the substrate W to the first height position P1. As a result, as illustrated in FIG. 17, the arm of the center robot CR supports the substrate W.

Thereafter, the controlling portion 102 controls the substrate holding portion 200 to release the holding of the substrate W by the chuck pin 202. The controlling portion 102 controls the moving mechanism 300 and the center robot CR to carry the substrate W supported by the arm of the center robot CR out of the chamber 11.

As described above, the processing on the substrate W ends.

In the present preferred embodiment, as described above, the moving mechanism 300 switches the state of the substrate W between the non-immersion state in which the substrate W is located outside the immersion bath 400 and the immersion state in which the substrate W is located inside the immersion bath 400 and immersed in the processing liquid by moving the substrate holding portion 200. Therefore, the substrate W located outside the immersion bath 400 can be immersed in the processing liquid to be processed. Therefore, since it is not necessary to continue to supply the processing liquid to the substrate W, it is possible to suppress an increase in the consumption amount of the processing liquid even when processing for a long time is required.

In addition, since the substrates W are immersed one by one in the immersion bath 400 and processed, it is possible to suppress particles of other substrates W from adhering (transferring) to a certain substrate W.

As described above, the substrate holding portion 200 includes the spin base 201 disposed above the substrate W and the plurality of chuck pins 202 protruding downward from the spin base 201 and holding the circumferential edge of the substrate W. Therefore, since the substrate W can be held from above, the substrate W can be easily immersed in the processing liquid in the immersion bath 400.

As described above, the first supplying portion 30 includes the nozzle 38 that ejects the processing liquid toward the upper surface Wa of the substrate W, and the nozzle 38 is provided in the spin base 201. Therefore, in the configuration in which the spin base 201 is provided above the substrate W, the processing liquid can be easily ejected to the upper surface Wa of the substrate W.

As described above, since the spin base 201 is rotated, the substrate holding portion 200 rotates the substrate W, and the nozzle 38 is disposed at the central portion of the spin base 201. Therefore, even in a case where the spin base 201 is rotated, for example, the nozzle 38 can be suppressed from being moved (rotated) around the rotational axis AX1.

As described above, by ejecting the processing liquid from the first supplying portion 30 and the second supplying portion 40 toward the substrate W, the processing liquid is stored in the immersion bath 400. Therefore, it is possible to perform the processing on the substrate W while storing the processing liquid.

As described above, by ejecting the processing liquid from the first supplying portion 30 and the second supplying portion 40 toward the upper surface Wa and the lower surface Wb of the substrate W, the processing liquid is stored in the immersion bath 400. Therefore, it is possible to perform the processing on the upper surface Wa and the lower surface Wb of the substrate W while storing the processing liquid. In addition, the time for storing the processing liquid in the immersion bath 400 can be shortened.

As described above, in a state in which the substrate holding portion 200 rotates the substrate W, the first supplying portion 30 and the second supplying portion 40 eject the processing liquid toward the substrate W and store the processing liquid in the immersion bath 400. Therefore, the processing liquid ejected onto the substrate W uniformly spreads on the substrate W due to the rotation of the substrate W. Therefore, the occurrence of processing unevenness can be suppressed.

As described above, when the first discharge portion 50 discharges the processing liquid in the immersion bath 400, the first supplying portion 30 ejects the processing liquid toward the substrate W. Therefore, it is possible to suppress the substrate W from being dried when the processing liquid in the immersion bath 400 is discharged. In addition, in a case where the substrate W is being rotated, it is possible to suppress the processing liquid bounced back on the side wall 402 of the immersion bath 400 from adhering to the substrate W. Thus, generation of particles can be suppressed.

As described above, in a state in which the rinse liquid is stored in the immersion bath 400, the first supplying portion 30 supplies the rinse liquid to the immersion bath 400 and causes the rinse liquid to overflow from the immersion bath 400. Therefore, the cup 450 provided around the periphery of the immersion bath 400 can be cleaned by the overflowed rinse liquid.

### Second Preferred Embodiment

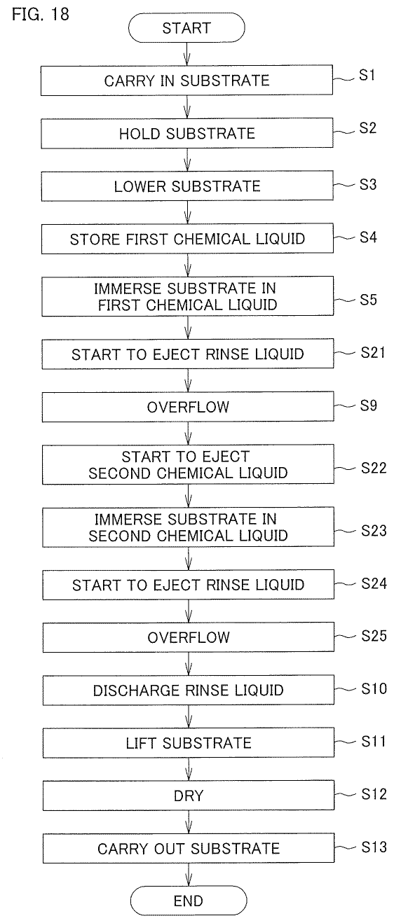

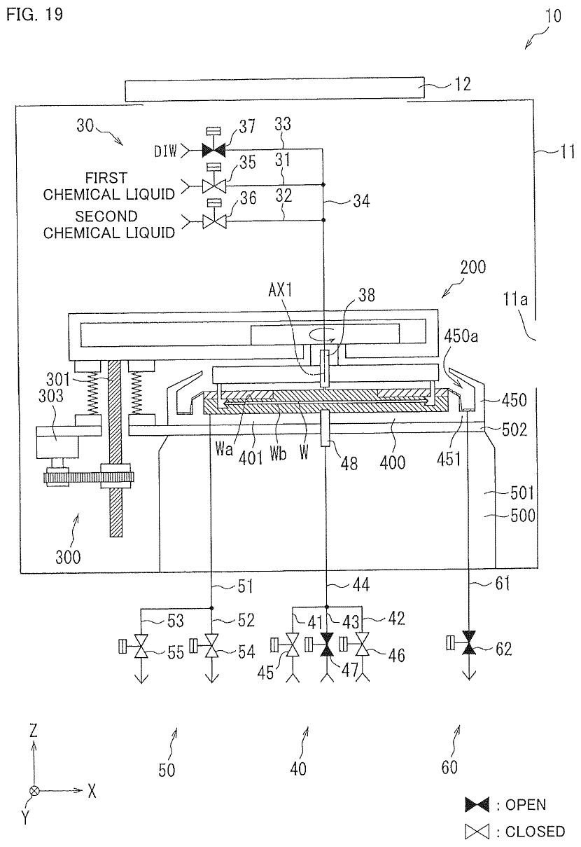

Next, a substrate processing method performed by a substrate processing apparatus 100 according to a second preferred embodiment of the present invention will be described with reference to FIGS. 18 to 22. In the second preferred embodiment, unlike the first preferred embodiment, an example in which the substrate W is processed by using a plurality of types (here, two types) of chemical liquids will be described. FIG. 18 is a flowchart illustrating a substrate processing method according to a second preferred embodiment. FIGS. 19 to 22 are schematic views for describing the substrate processing method according to the second preferred embodiment. The substrate processing method performed by the substrate processing apparatus 100 according to the second preferred embodiment includes steps S1 to S5, step S21, step S9, steps S22 to S25, and steps S10 to S13. Note that steps S23 and S25 are an example of an “immersion step” of the present invention. A configuration of the substrate processing apparatus 100 of the second preferred embodiment is similar to that of the first preferred embodiment.

As illustrated in FIG. 18, steps S1 to S5 are the same as those in the first preferred embodiment. After step S5, the processing proceeds to step S21.

In step S21, the ejection of the rinse liquid is started. Specifically, as illustrated in FIG. 19, the controlling portion 102 switches the opening/closing valve 37 and the opening/closing valve 47 from the closed state to the open state when a predetermined time has elapsed from the start of discharge of the first chemical liquid. As a result, the rinse liquid is ejected from the nozzles 38 and 48. Therefore, the first chemical liquid in the immersion bath 400 overflows, and the processing liquid in the immersion bath 400 is gradually replaced from the first chemical liquid to the rinse liquid. In step S21, the controlling portion 102 preferably controls the substrate holding portion 200 to rotate the substrate W. By rotating the substrate W, the liquid can be efficiently replaced.

Next, in step S9, the rinse liquid is caused to overflow. Specifically, as illustrated in FIG. 13, the controlling portion 102 maintains the opening/closing valve 37 and the opening/closing valve 47 in the open state. As a result, the upper surface Wa and the lower surface Wb of the substrate W are rinsed, and the first chemical liquid in the immersion bath 400 is replaced with the rinse liquid. Therefore, the rinse liquid is stored in the immersion bath 400, and the substrate W is immersed in the rinse liquid. The rinse liquid in the immersion bath 400 overflows after filling the inner space 400a of the immersion bath 400. That is, in a state in which the rinse liquid is stored in the immersion bath 400, the rinse liquid is supplied to the immersion bath 400, and the rinse liquid overflows from the immersion bath 400. As a result, the cup 450 is cleaned by the overflowed rinse liquid.

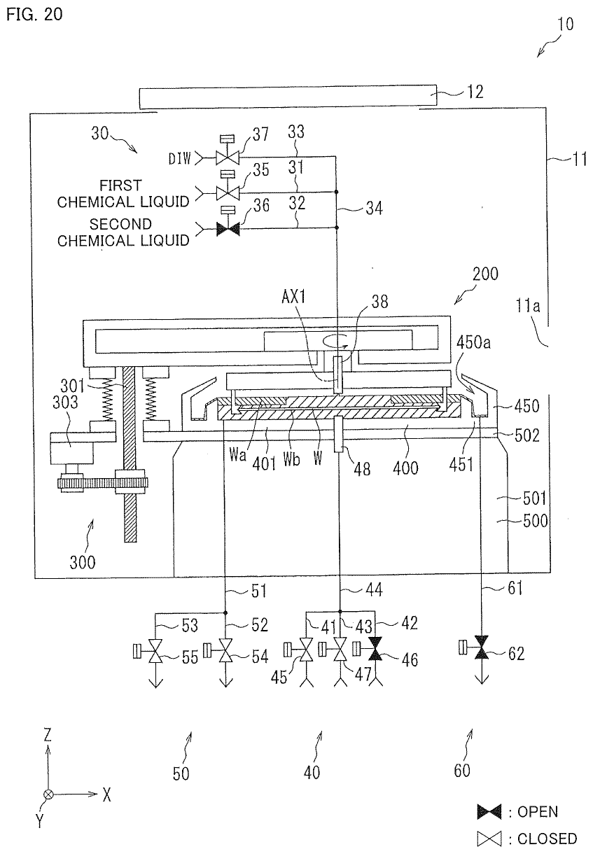

Next, in step S22, the ejection of the second chemical liquid is started. Specifically, as illustrated in FIG. 20, the controlling portion 102 switches the opening/closing valve 36 and the opening/closing valve 46 from the closed state to the open state when a predetermined time has elapsed from the start of discharge of the rinse liquid. At that time, the controlling portion 102 switches the opening/closing valve 37 and the opening/closing valve 47 from the open state to the closed state. As a result, the second chemical liquid is ejected from the nozzles 38 and 48. Therefore, the rinse liquid in the immersion bath 400 overflows, and the processing liquid in the immersion bath 400 is gradually replaced from the rinse liquid to the second chemical liquid.

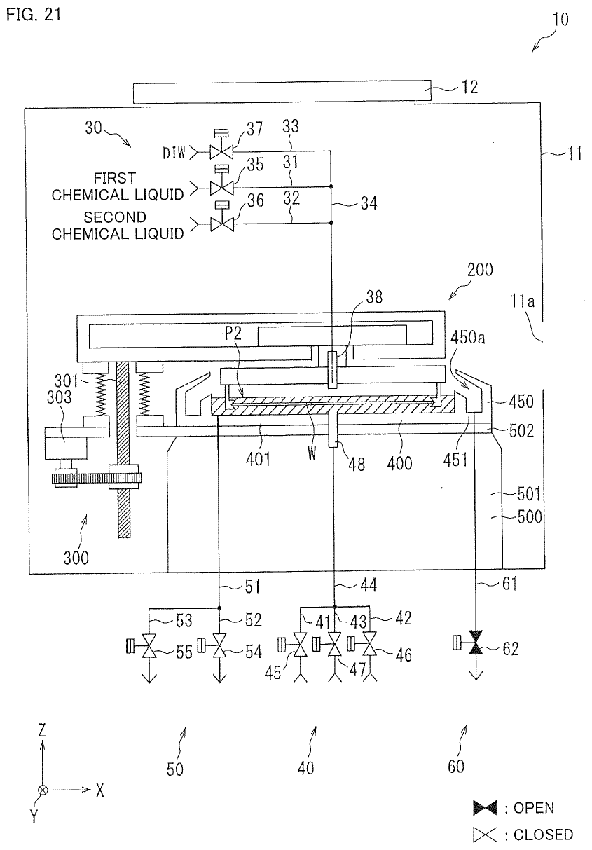

Next, in step S23, the substrate W is immersed in the second chemical liquid. Specifically, as illustrated in FIG. 21, when a predetermined time has elapsed from the start of ejection of the second chemical liquid and the processing liquid in the immersion bath 400 has been replaced from the rinse liquid to the second chemical liquid, the controlling portion 102 switches the opening/closing valve 36 and the opening/closing valve 46 from the open state to the closed state. As a result, the substrate W is immersed in the second chemical liquid.

At that time, the controlling portion 102 controls the substrate holding portion 200 to stop the rotation of the substrate W. Note that the controlling portion 102 need not stop the rotation of the substrate W. That is, the controlling portion 102 may continue the rotation of the substrate W. In this case, the rotational speed of the substrate W may be, for example, several tens rpm or more and several hundreds rpm or less.

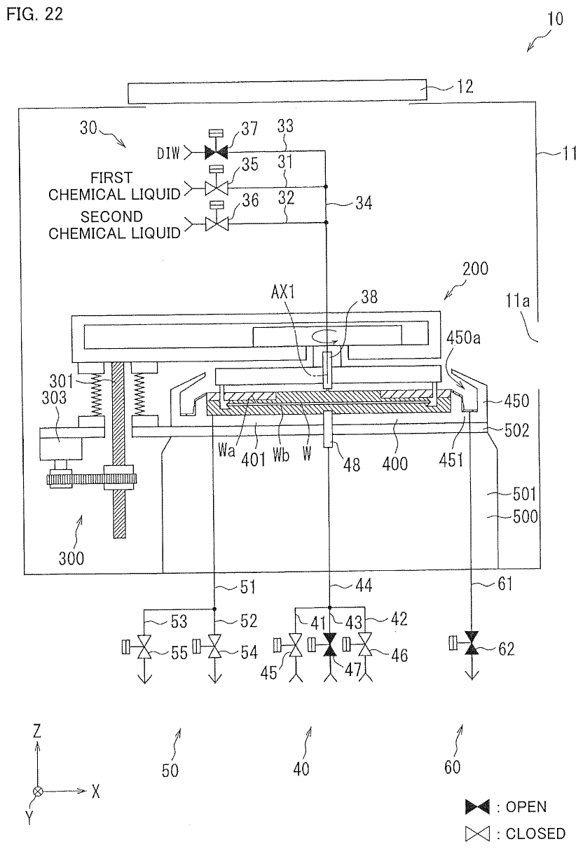

Next, in step S24, the ejection of the rinse liquid is started. Specifically, as illustrated in FIG. 22, the controlling portion 102 switches the opening/closing valve 37 and the opening/closing valve 47 from the closed state to the open state when a predetermined time has elapsed from the start of discharge of the second chemical liquid. As a result, the rinse liquid is ejected from the nozzles 38 and 48. Thus, the second chemical liquid in the immersion bath 400 overflows, and the processing liquid in the immersion bath 400 is gradually replaced from the second chemical liquid to the rinse liquid. In step S24, the controlling portion 102 preferably controls the substrate holding portion 200 to rotate the substrate W.

Next, in step S25, the rinse liquid is caused to overflow. Specifically, as illustrated in FIG. 13, the controlling portion 102 maintains the opening/closing valve 37 and the opening/closing valve 47 in the open state. As a result, the upper surface Wa and the lower surface Wb of the substrate W are rinsed, and the second chemical liquid in the immersion bath 400 is replaced with the rinse liquid. Therefore, the rinse liquid is stored in the immersion bath 400, and the substrate W is immersed in the rinse liquid. The rinse liquid in the immersion bath 400 overflows after filling the inner space 400a of the immersion bath 400. That is, in a state in which the rinse liquid is stored in the immersion bath 400, the rinse liquid is supplied to the immersion bath 400, and the rinse liquid overflows from the immersion bath 400. As a result, the cup 450 is cleaned by the overflowed rinse liquid.

Next, steps S10 to S13 are executed in the same manner as in the first preferred embodiment.

As described above, the processing on the substrate W ends. Other substrate processing methods of the second preferred embodiment are the same as those of the first preferred embodiment.

In the second preferred embodiment, as described above, when the processing liquid in the immersion bath 400 is replaced (steps S21, S22 and S24), the processing liquid in the immersion bath 400 is caused to overflow. Therefore, the processing liquid can be replaced in a state in which the substrate W is immersed in the processing liquid. Therefore, for example, even in a case where the substrate W is processed with two types of chemical liquids, it is possible to easily suppress air from coming into contact with the surface of the substrate W during processing using the two types of chemical liquids.

Other effects of the second preferred embodiment are the same as those of the first preferred embodiment.

### First Modification Example

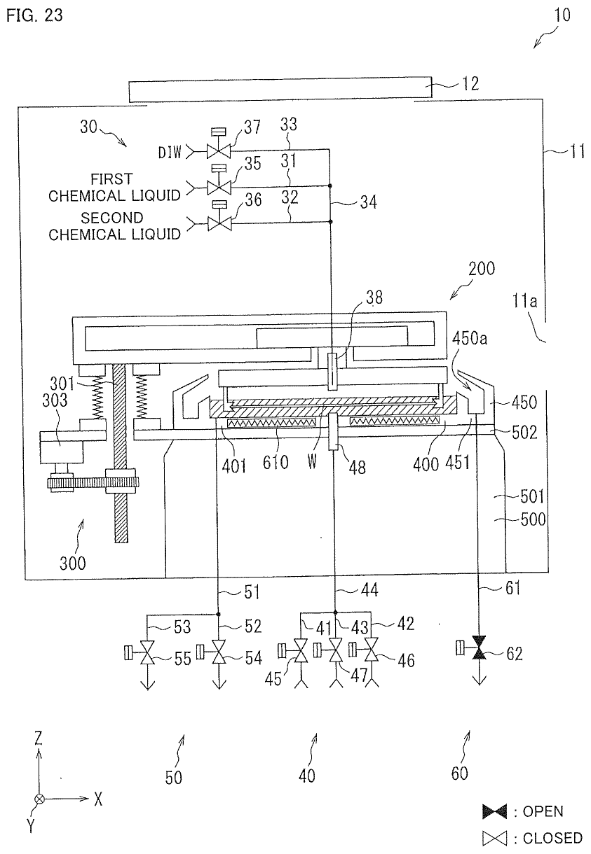

Next, a substrate processing apparatus 100 according to a first modification example of the present invention will be described with reference to FIG. 23. FIG. 23 is a schematic view illustrating the substrate processing apparatus 100 according to the first modification example. In the first modification example, unlike the first preferred embodiment and the second preferred embodiment, an example of heating a processing liquid in the immersion bath 400 will be described. Note that in the following description, a portion of the first preferred embodiment will be modified, but the first modification example is also applicable to the second preferred embodiment.

As illustrated in FIG. 23, the substrate processing apparatus 100 includes a heater 610 that heats the processing liquid. The heater 610 heats the processing liquid in the immersion bath 400. Specifically, the heater 610 is disposed, for example, inside the bottom wall 401 of the immersion bath 400. For example, the heater 610 may be disposed to be in contact with the bottom surface of the bottom wall 401 of the immersion bath 400. For example, the heater 610 is disposed over one turn to surround the periphery of the nozzle 48. The heater 610 heats the processing liquid stored in the immersion bath 400 by heating the immersion bath 400.

The controlling portion 102 controls the heater 610. The controlling portion 102 controls the heater 610 to heat the processing liquid in the immersion bath 400 to a predetermined temperature. Specifically, the controlling portion 102 performs ON/OFF control of the heater 610 to maintain the processing liquid in the immersion bath 400 at a predetermined temperature. In this case, the substrate processing apparatus 100 includes, for example, a temperature sensor (not illustrated) that measures the temperature of the immersion bath 400 or the temperature of the processing liquid. Note that in the first modification example, the first supplying portion 30 and the second supplying portion 40 are preferably provided with a heater (not illustrated) that heats the processing liquid to a predetermined temperature.

In the first modification example, as described above, by providing the heater 610 that heats the processing liquid in the immersion bath 400, it is possible to suppress a decrease in the temperature of the processing liquid in the immersion bath 400. Therefore, for example, even in a case where the immersion processing is performed for a long time, it is possible to suppress a decrease in the temperature of the processing liquid. In addition, by heating the processing liquid in the immersion bath 400 to a predetermined temperature, for example, the substrate W can be processed with a processing liquid at a constant temperature.

Other configurations and other effects of the first modification example are similar to those of the first preferred embodiment and the second preferred embodiment.

### Second Modification Example

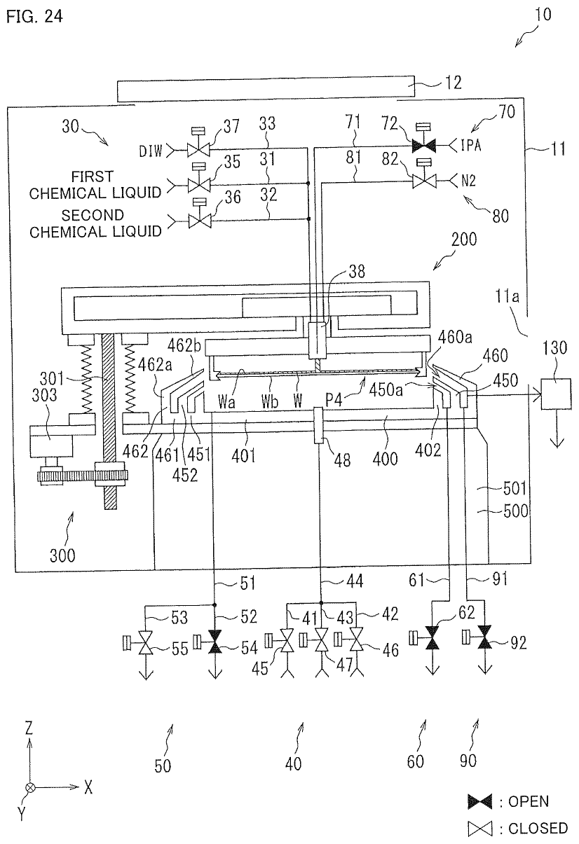

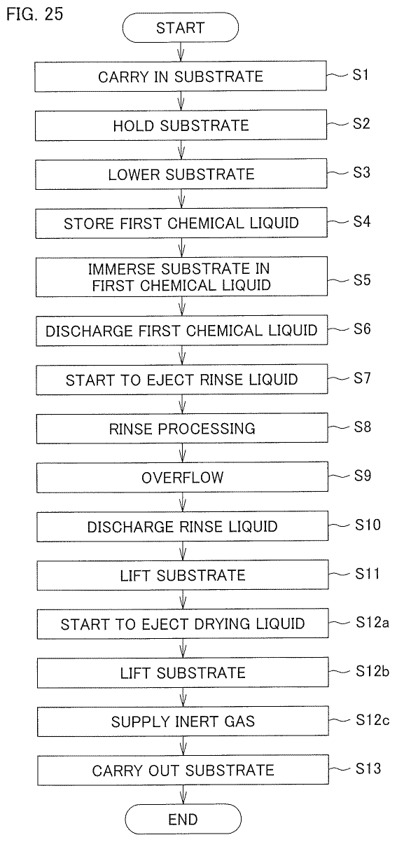

Next, a substrate processing apparatus 100 according to a second modification example of the present invention will be described with reference to FIGS. 24 and 25. FIG. 24 is a schematic view illustrating the substrate processing apparatus 100 according to the second modification example. In the second modification example, unlike the first preferred embodiment, the second preferred embodiment, etc., an example in which a drying liquid and a gas are ejected (supplied) to the substrate W when the substrate W is dried will be described. Note that in the following description, a portion of the first preferred embodiment will be modified, but the second modification example is also applicable to the second preferred embodiment, etc.

As illustrated in FIG. 24, the substrate processing apparatus 100 includes a third supplying portion 70 and a fourth supplying portion 80. The third supplying portion 70 is an example of a “processing liquid supplying portion” of the present invention.

The third supplying portion 70 supplies a drying liquid to the substrate W. In the second modification example, the third supplying portion 70 supplies the drying liquid toward the upper surface Wa of the substrate W held by the substrate holding portion 200. The drying liquid is, for example, isopropyl alcohol (IPA).

The third supplying portion 70 includes a drying liquid piping 71 and an opening/closing valve 72. The drying liquid piping 71 is a tubular member through which the drying liquid flows. The drying liquid is supplied from a supply source to the drying liquid piping 71. The downstream end of the drying liquid piping 71 is connected to the nozzle 38. The drying liquid piping 71 allows the drying liquid to flow through the nozzle 38.

The opening/closing valve 72 is provided in the drying liquid piping 71 and opens and closes a flow path in the drying liquid piping 71. The opening/closing valve 72 adjusts the opening degree of the drying liquid piping 71 to adjust a flow rate of the drying liquid supplied to the drying liquid piping 71.

In the second modification example, a flow path through which the drying liquid passes is formed in the nozzle 38 in addition to a flow path through which the liquid from the first supplying portion 30 passes. The nozzle 38 ejects the drying liquid toward the upper surface Wa of the substrate W held by the substrate holding portion 200.

The fourth supplying portion 80 supplies a gas to the substrate W. In the second modification example, the fourth supplying portion 80 supplies the gas toward the upper surface Wa of the substrate W held by the substrate holding portion 200. The gas supplied by the fourth supplying portion 80 is not particularly limited, but is preferably an inert gas such as a nitrogen gas (N₂ gas), a helium gas (He gas), or an argon gas (Ar gas). In the second modification example, the gas supplied by the fourth supplying portion 80 is a nitrogen gas.

The fourth supplying portion 80 includes a gas piping 81 and an opening/closing valve 82. The gas piping 81 is a tubular member through which an inert gas flows. An inert gas is supplied from a supply source to the gas piping 81. The downstream end of the gas piping 81 is connected to the nozzle 38. The gas piping 81 allows the inert gas to flow through the nozzle 38.

The opening/closing valve 82 is provided in the gas piping 81 and opens and closes a flow path in the gas piping 81. The opening/closing valve 82 adjusts the opening degree of the gas piping 81 to adjust a flow rate of the inert gas supplied to the gas piping 81.

In the second modification example, the nozzle 38 is provided with a flow path through which the inert gas passes in addition to a flow path through which the liquid from the first supplying portion 30 passes and a flow path through which the drying liquid passes. The nozzle 38 ejects the inert gas toward the upper surface Wa of the substrate W held by the substrate holding portion 200.

In the second modification example, the substrate processing apparatus 100 further includes an outer cup 460 outside the cup 450. The outer cup 460 is disposed around the periphery of the cup 450. In the second modification example, in the outer cup 460, the outer cup 460, the cup 450, and the immersion bath 400 are integrally formed. In other words, the outer cup 460, the cup 450, and the immersion bath 400 are a single member.

The outer cup 460 is disposed outside the side wall 452 of the cup 450 at a predetermined distance from the side wall 452. Specifically, the outer cup 460 has a bottom wall 461 and a side wall 462. The bottom wall 461 is connected to the bottom wall 451 or the side wall 452 of the cup 450. The side wall 462 is connected to a peripheral edge portion of the bottom wall 461. The side wall 462 has a lower wall portion 462a and an upper wall portion 462b. The lower wall portion 462a extends upward from the bottom wall 461. The upper wall portion 462b is inclined inward and upward from the upper end of the lower wall portion 462a. The bottom wall 461 and the side wall 462 of the outer cup 460 and the side wall 452 of the cup 450 define an inner space 460a of the outer cup 460.

For example, the outer cup 460 collects the drying liquid that is scattered around the periphery of the substrate W due to the rotation of the substrate W. A gas discharge portion 130 is connected to the outer cup 460, and a gas in the inner space 460a is discharged out of the chamber 11. The gas discharge portion 130 includes, for example, an exhaust piping and an exhaust fan disposed inside the exhaust piping.

The substrate processing apparatus 100 includes a third discharge portion 90. The third discharge portion 90 discharges the drying liquid in the outer cup 460 out of the outer cup 460. In the second modification example, the third discharge portion 90 discharges the drying liquid in the outer cup 460 out of the chamber 11. Specifically, the third discharge portion 90 includes a drain piping 91 and an opening/closing valve 92. Since the third discharge portion 90 is configured similarly to the second discharge portion 60, the description thereof will be omitted.

The controlling portion 102 controls the third supplying portion 70, the fourth supplying portion 80, and the third discharge portion 90.

Next, a substrate processing method according to the second modification example will be described with reference to FIGS. 24 and 25. FIG. 25 is a flowchart illustrating a substrate processing method according to the second modification example. The substrate processing method performed by the substrate processing apparatus 100 according to the second modification example includes steps S1 to S11, steps S12a to S12c, and step S13.

As illustrated in FIG. 25, steps S1 to S11 are the same as those in the first preferred embodiment. After step S11, the processing proceeds to step S12a.

In step S12a, the ejection of the drying liquid is started. Specifically, the controlling portion 102 switches the opening/closing valve 37 and the opening/closing valve 47 from the open state to the closed state, and switches the opening/closing valve 72 from the closed state to the open state. As a result, the first chemical liquid is not supplied to the substrate W, and the drying liquid is supplied thereto.

Next, in step S12b, the substrate W is lifted. Specifically, as illustrated in FIG. 24, the controlling portion 102 moves the substrate holding portion 200 to a fourth height position P4 where the substrate W faces the side wall 462 of the outer cup 460 in the horizontal direction. The fourth height position P4 is lower than the first height position P1 and higher than the third height position P3. The substrate W is disposed at a height position between the upper end (inner circumferential end) of the side wall 452 of the cup 450 and the upper end (inner circumferential end) of the side wall 462 of the outer cup 460 in a state of being disposed at the fourth height position P4. That is, the side surface of the substrate W faces the inner space 460a.

Next, in step S12c, a gas is supplied to the substrate W. Specifically, the controlling portion 102 switches the opening/closing valve 72 from the open state to the closed state, and switches the opening/closing valve 82 from the closed state to the open state. As a result, the drying liquid is not supplied to the substrate W, and the inert gas is supplied thereto. The substrate W is then dried.

The controlling portion 102 switches the opening/closing valve 82 from the open state to the closed state when a predetermined time has elapsed from the start of supply of the inert gas. Thereafter, the controlling portion 102 controls the substrate holding portion 200 to stop the rotation of the substrate W.

Next, step S13 is executed in the same manner as in the first preferred embodiment.

Other configurations and other substrate processing methods of the second modification example are similar to those of the first preferred embodiment, the second preferred embodiment, etc.

In the second modification example, as described above, the outer cup 460 is provided around the periphery of the cup 450, and when the substrate W is dried, the substrate W is disposed at the height position (fourth height position P4) of horizontally facing the side wall 462 of the outer cup 460. Therefore, the substrate W can be dried at the height position of the outer cup 460 where the first chemical liquid and/or the second chemical liquid do not flow. Therefore, for example, a mist of the first chemical liquid and/or the second chemical liquid can be suppressed from adhering to the substrate W and adversely affecting the substrate W.

Other effects of the second modification example are similar to those of the first preferred embodiment, the second preferred embodiment, etc.

### Third Modification Example

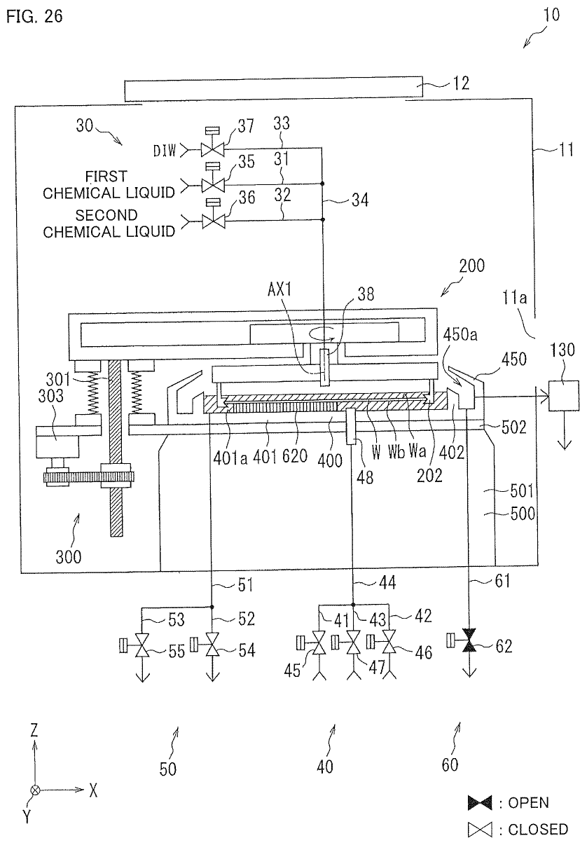

Next, a substrate processing apparatus 100 according to a third modification example of the present invention will be described with reference to FIG. 26. FIG. 26 is a schematic view illustrating the substrate processing apparatus 100 according to the third modification example. In the third modification example, unlike the first preferred embodiment, the second preferred embodiment, etc., an example in which a brush 620 is provided in the immersion bath 400 will be described. Note that in the following description, a portion of the second preferred embodiment will be modified, but the third modification example is also applicable to the first preferred embodiment, etc.

As illustrated in FIG. 26, the substrate processing apparatus 100 includes the brush 620. The brush 620 is disposed in the immersion bath 400. The brush 620 is provided to clean the lower surface Wb of the substrate W.

The brush 620 may include, for example, a porous material such as sponge. In addition, the brush 620 may contain, for example, a resin such as polyvinyl alcohol (PVA). In addition, the brush 620 may be configured by combining a plurality of members. In addition, the brush 620 may include a plurality of bristles.

The brush 620 is fixed to an upper surface 401a of the bottom wall 401 of the immersion bath 400. The brush 620 comes into contact with the lower surface Wb of the substrate W to clean the lower surface Wb of the substrate W in a state in which the substrate W is immersed in the processing liquid stored in the immersion bath 400.

The brush 620 comes into contact with the substrate W that is being rotated to clean the substrate W. The brush 620 is disposed, for example, on an extension line of the rotational axis AX1 of the substrate holding portion 200. In other words, the brush 620 is disposed in a region including the center of the upper surface of the bottom wall 401 of the immersion bath 400. The brush 620 is disposed radially outward from the central portion of the bottom wall 401. The brush 620 is formed in, for example, a substantially fan shape, a belt shape, or a linear shape in plan view. In the third modification example, the nozzle 48 is disposed at a position shifted from the center of the bottom wall 401 of the immersion bath 400. Note that the brush 620 may be, for example, formed in a circular shape in plan view.

In the third modification example, for example, in step S5 of the processing flow, the lower surface Wb of the substrate W is cleaned by the brush 620. At that time, in the third modification example, in a state in which the substrate W is rotated by the substrate holding portion 200, the brush 620 comes into contact with the lower surface Wb of the substrate W to clean the lower surface Wb of the substrate W. In this case, step S5, step S9, step S23 and/or step S25 are examples of an “immersion step” and a “cleaning step” of the present invention.

In the third modification example, as described above, the brush 620 is provided on the upper surface 401a of the bottom wall 401 of the immersion bath 400, and the brush 620 comes into contact with the lower surface Wb of the substrate W to clean the lower surface Wb of the substrate W in a state in which the substrate W is immersed in the processing liquid stored in the immersion bath 400. Therefore, since the brush 620 comes into contact with the substrate W in a state of being immersed in the processing liquid, the cleaning effect can be improved.

As described above, the substrate holding portion 200 rotates the substrate W while the lower surface Wb of the substrate W is in contact with the brush 620. Therefore, the cleaning effect can be further improved. In addition, by rotating the substrate W, substantially the entire lower surface Wb of the substrate W can be easily cleaned by the brush 620.

In a case where the brush 620 is provided, as in the second preferred embodiment, the brush 620 can be suppressed from drying by replacing the processing liquid through overflowing. Therefore, generation of particles can be suppressed.

Other configurations, substrate processing methods, and effects of the third modification example are the same as those of the first preferred embodiment, the second preferred embodiment, etc.

### Fourth Modification Example

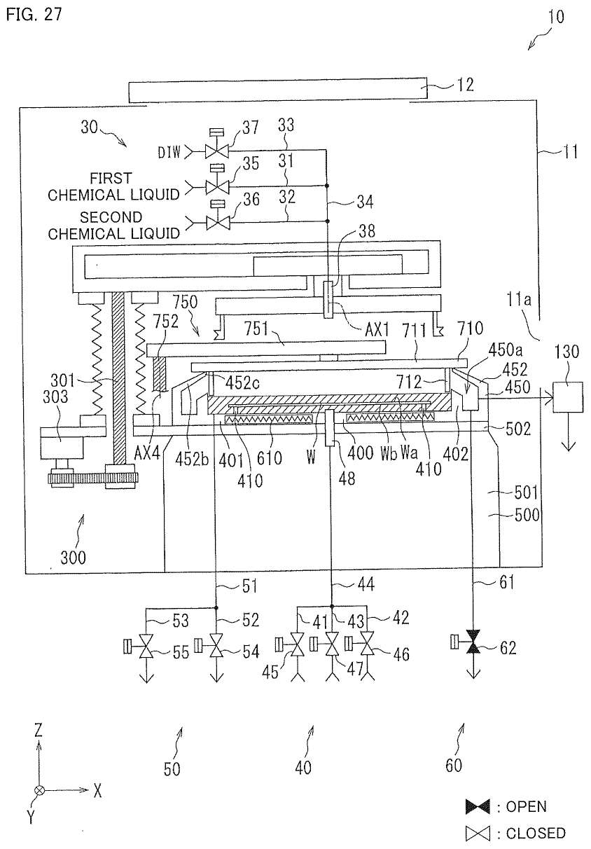

Next, a substrate processing apparatus 100 according to a fourth modification example of the present invention will be described with reference to FIG. 27. FIG. 27 is a schematic view illustrating the substrate processing apparatus 100 according to the fourth modification example. In the fourth modification example, unlike the first preferred embodiment, the second preferred embodiment, etc., an example in which the substrate processing apparatus 100 includes a lid 710 will be described. Note that in the following description, a portion of the first modification example will be modified, but the fourth modification example is also applicable to the first preferred embodiment, the second preferred embodiment, etc.

As illustrated in FIG. 27, the substrate processing apparatus 100 includes the lid 710 and a lid moving mechanism 750 that moves the lid 710. The lid 710 covers an inner circumferential edge 452c of the cup 450. Specifically, the cup 450 has the inner circumferential edge 452c defining an opening through which the substrate W can pass. The inner circumferential edge 452c is formed by the upper end of the upper wall portion 452b of the side wall 452.

The lid 710 includes, for example, a plate-shaped plate 711 and a circular cylindrical portion 712 having a circular cylindrical shape. The plate 711 has, for example, a circular shape. The circular cylindrical portion 712 protrudes downward from the lower surface of the plate 711.

The plate 711 has a diameter larger than the diameter of the inner circumferential edge 452c of the cup 450. The plate 711 covers the upper side of the inner circumferential edge 452c in a state of being disposed on the cup 450. In addition, the circular cylindrical portion 712 has a diameter (outer diameter) smaller than the diameter of the inner circumferential edge 452c of the cup 450. The circular cylindrical portion 712 covers the inside of the inner circumferential edge 452c in a state of being inserted into the inside (radially inside) of the cup 450. In the fourth modification example, the circular cylindrical portion 712 is formed from the upper end of the side wall 452 of the cup 450 to the upper end of the side wall 402 of the immersion bath 400 in the up-down direction.

The lid moving mechanism 750 moves the lid 710 separately from the substrate holding portion 200. Specifically, the lid moving mechanism 750 moves the lid 710 in the vertical direction. That is, the lid moving mechanism 750 lifts and lowers the lid 710. The lid moving mechanism 750 rotates the lid 710 about a rotational axis AX4. The lid moving mechanism 750 includes, for example, a ball screw mechanism and an electric motor that applies a driving force to the ball screw mechanism.

Specifically, the lid moving mechanism 750 may be, for example, configured similarly to the moving mechanism 300. The lid moving mechanism 750 includes, for example, a supporting portion 751 that supports the lid 710 and a screw shaft 752. In addition, the lid moving mechanism 750 includes a nut, an electric motor, a driving belt, and a shaft cover (none of which are illustrated). Since the screw shaft 752, the nut, the electric motor, the driving belt, and the shaft cover of the lid moving mechanism 750 are configured similarly to the moving mechanism 300, the description thereof will be omitted. The lid moving mechanism 750 includes a rotation mechanism (not illustrated) that rotates the screw shaft 752 and the driving motor about the rotational axis AX4 that is a central axis of the screw shaft 752. As a result, the lid 710 can be retracted from the position immediately above the substrate W.

In the fourth modification example, a support table 410 is provided on the bottom wall 401 of the immersion bath 400. The support table 410 supports the substrate W. The support table 410 protrudes upward from the upper surface of the bottom wall 401. The support table 410 is not particularly limited, but has, for example, a cylindrical shape. A plurality of support tables 410 are provided on the bottom wall 401. Note that the support table 410 and the bottom wall 401 may be integrally formed. In other words, the support table 410 and the bottom wall 401 may be a single member.

In the fourth modification example, for example, in step S5 of the processing flow, the controlling portion 102 controls the substrate holding portion 200 to place the substrate W on the plurality of support tables 410. As a result, the substrate W is immersed in the processing liquid stored in the immersion bath 400. In addition, the controlling portion 102 controls the substrate holding portion 200 to retract the substrate holding portion 200 upward from the cup 450.

The controlling portion 102 then controls the lid moving mechanism 750 to place the lid 710 on the cup 450.

In the fourth modification example, as described above, the substrate processing apparatus 100 includes the lid 710 that covers the inner circumferential edge 452c of the cup 450. Therefore, it is possible to suppress the gas above the immersion bath 400 from being drawn into the inner space 450a of the cup 450. Therefore, it is possible to suppress a decrease in the temperature of the processing liquid in the immersion bath 400 due to the airflow drawn into the inner space 450a.

As described above, the lid moving mechanism 750 that moves the lid 710 separately from the substrate holding portion 200 is provided. Therefore, the lid 710 can be easily moved to cover the inner circumferential edge 452c of the immersion bath 400.

Other configurations, substrate processing methods, and effects of the fourth modification example are similar to those of the first modification example, etc.

### Fifth Modification Example

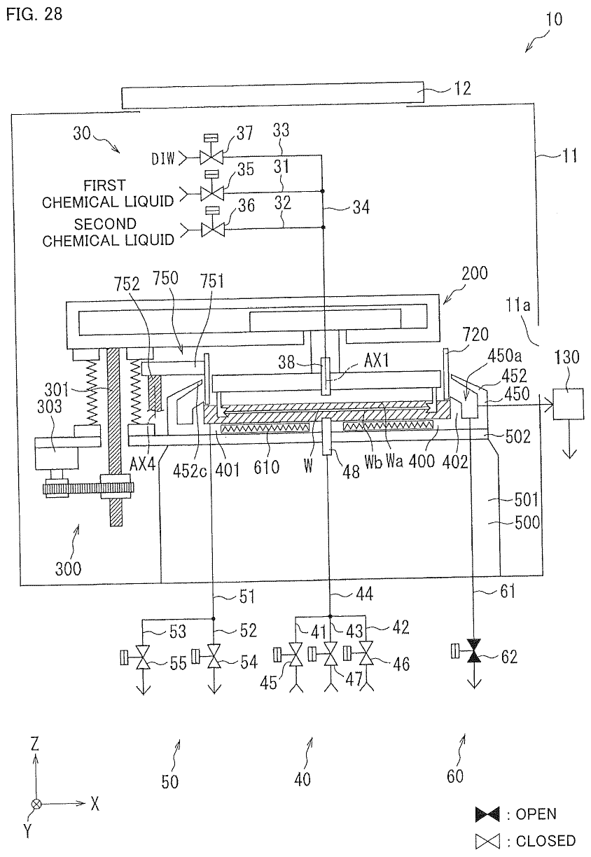

Next, a substrate processing apparatus 100 according to a fifth modification example of the present invention will be described with reference to FIG. 28. FIG. 28 is a schematic view illustrating the substrate processing apparatus 100 according to the fifth modification example. In the fifth modification example, unlike the fourth modification example, an example will be described in which the temperature decrease of the processing liquid is suppressed by a lid 720 in a state in which the substrate W is held by the substrate holding portion 200.

As illustrated in FIG. 28, the substrate processing apparatus 100 includes the lid 720 and the lid moving mechanism 750 that moves the lid 720. The lid 720 covers the inner circumferential edge 452c of the cup 450. Specifically, the lid 720 has a circular cylindrical shape. The lid 720 extends in the up-down direction.

The lid 720 has a diameter (outer diameter) smaller than the inner circumferential edge 452c of the cup 450. The lid 720 covers the inside of the inner circumferential edge 452c in a state of being inserted into the inside (radially inside) of the cup 450. The lid 720 is formed from the upper end of the side wall 452 of the cup 450 to the upper end of the side wall 402 of the immersion bath 400 in the up-down direction. That is, the lid 720 covers the inlet of the inner space 450a.

In addition, the lid 720 has an inner diameter larger than the diameter of the spin base 201. Thus, the spin base 201 can be disposed inside the lid 720. Note that other configurations of the lid 720 are similar to those of the circular cylindrical portion 712 of the lid 710.

The lid moving mechanism 750 moves the lid 720. Specifically, the lid moving mechanism 750 moves the lid 720 in the vertical direction. That is, the lid moving mechanism 750 lifts and lowers the lid 720. The lid moving mechanism 750 rotates the lid 720 about the rotational axis AX4. The supporting portion 751 of the lid moving mechanism 750 is fixed to, for example, the outer peripheral surface of the lid 720. Other configurations of the lid moving mechanism 750 are similar to those of the fourth modification example.

In the fifth modification example, unlike the fourth modification example, the support table 410 is not provided in the immersion bath 400.

In the fifth modification example, for example, prior to step S5 of the processing flow, the controlling portion 102 controls the lid moving mechanism 750 to insert the lid 720 into the cup 450. As a result, in step S5, the lid 720 covers the inside of the inner circumferential edge 452c of the cup 450, and the substrate W is immersed in the processing liquid in a state of being held by the substrate holding portion 200.

Other configurations, substrate processing methods, and effects of the fifth modification example are similar to those of the fourth modification example.

### Sixth Modification Example

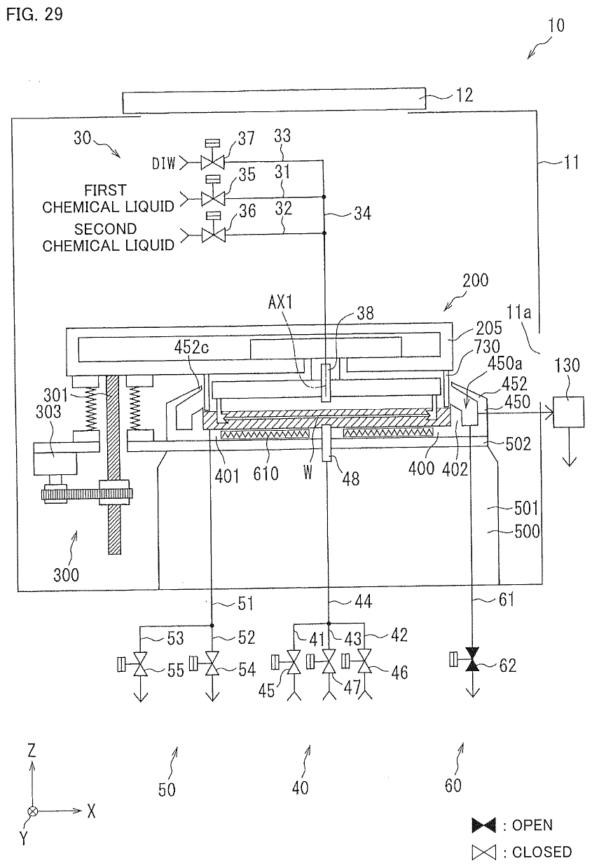

Next, a substrate processing apparatus 100 according to a sixth modification example of the present invention will be described with reference to FIG. 29. FIG. 29 is a schematic view illustrating the substrate processing apparatus 100 according to the sixth modification example. In the sixth modification example, unlike the fourth modification example and the fifth modification example, an example in which the lid moving mechanism 750 is not provided will be described.

As illustrated in FIG. 29, the substrate processing apparatus 100 includes a lid 730. In the sixth modification example, unlike the fifth modification example, the lid moving mechanism 750 is not provided. The lid 730 covers the inner circumferential edge 452c of the cup 450. The upper end of the lid 730 is fixed to the housing 205 of the substrate holding portion 200. In the sixth modification example, the lid 730 surrounds the periphery of the spin base 201. Other configurations of the lid 730 are similar to those of the lid 720 of the fifth modification example.

In the sixth modification example, for example, in step S5 of the processing flow, the lid 730 covers the inside of the inner circumferential edge 452c of the cup 450, and the substrate W is immersed in the processing liquid in a state of being held by the substrate holding portion 200.

In the sixth modification example, as described above, the lid 730 is provided in the substrate holding portion 200. Therefore, it is not necessary to provide the lid moving mechanism 750 for moving the lid 730.

Other configurations, substrate processing methods, and effects of the sixth modification example are similar to those of the fifth modification example.

### Seventh Modification Example

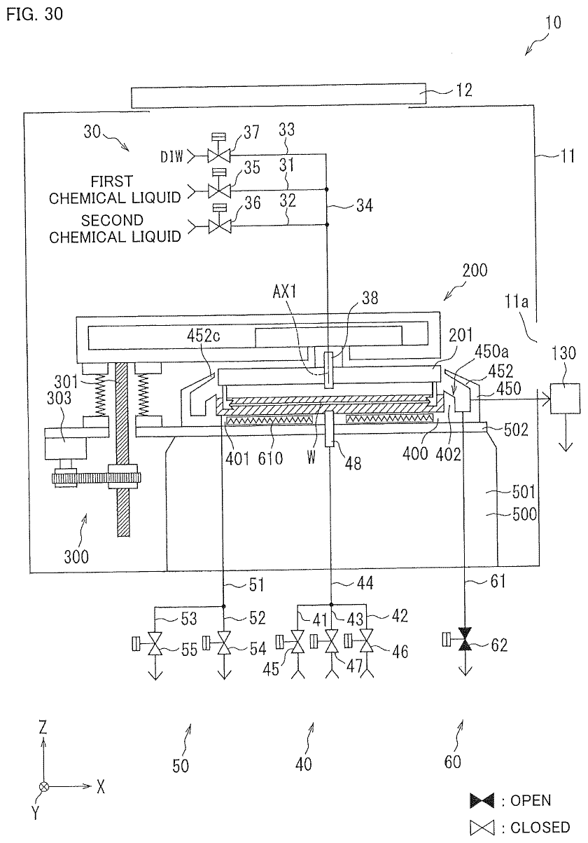

Next, a substrate processing apparatus 100 according to a seventh modification example of the present invention will be described with reference to FIG. 30. FIG. 30 is a schematic view illustrating the substrate processing apparatus 100 according to the seventh modification example. In the seventh modification example, unlike the fourth to sixth modification examples, an example in which the spin base 201 also serves as a lid will be described. Note that in the following description, a portion of the first modification example will be modified, but the seventh modification example is also applicable to the first preferred embodiment, the second preferred embodiment, etc.

As illustrated in FIG. 30, the spin base 201 of the substrate holding portion 200 also serves as a lid. In the seventh modification example, unlike the fourth modification example to the sixth modification example, the substrate processing apparatus 100 does not include the lids 710 to 730 and the lid moving mechanism 750. In the seventh modification example, the spin base 201 covers the inner circumferential edge 452c of the cup 450. In the seventh modification example, the spin base 201 has a diameter (outer diameter) slightly smaller than the inner diameter of the inner circumferential edge 452c of the cup 450. Therefore, the gap between the outer peripheral surface of the spin base 201 and the inner circumferential edge 452c of the cup 450 in the seventh modification example is smaller than the gap between the outer peripheral surface of the spin base 201 and the inner circumferential edge 452c of the cup 450 in the first modification example.

In the seventh modification example, since the spin base 201 also serves as a lid as described above, it is possible to suppress an increase in the number of components.

Other configurations, substrate processing methods, and effects of the seventh modification example are similar to those of the first modification example.

### Eighth Modification Example

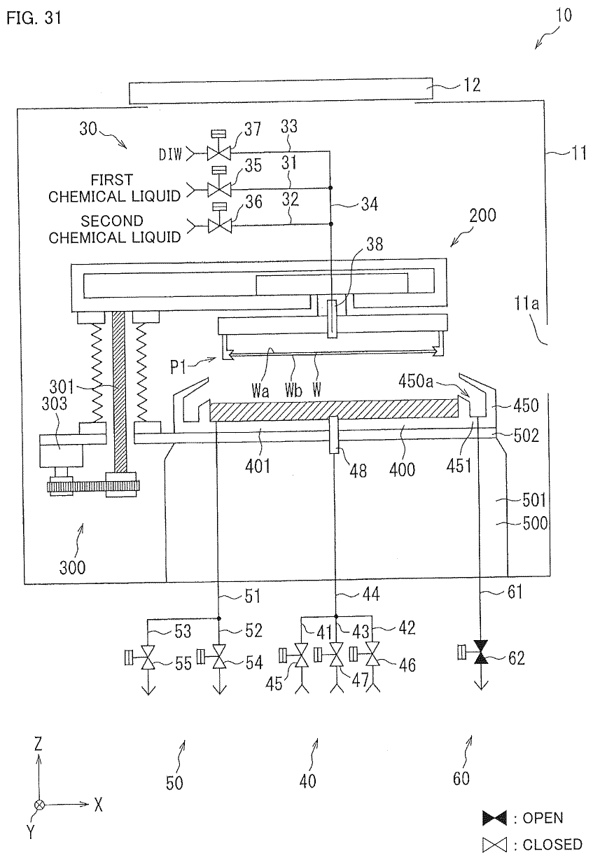

Next, a substrate processing apparatus 100 according to an eighth modification example of the present invention will be described with reference to FIG. 31. FIG. 31 is a schematic view illustrating the substrate processing apparatus 100 according to the eighth modification example. In the eighth modification example, unlike the first preferred embodiment, the second preferred embodiment, etc., an example in which a processing liquid is stored in advance in the immersion bath 400 and the substrate W is immersed in the processing liquid stored in the immersion bath 400 will be described. Note that in the following description, a portion of the first preferred embodiment will be modified, but the eighth modification example is also applicable to the second preferred embodiment, etc.

As illustrated in FIG. 31, a processing liquid is stored in advance in the immersion bath 400. In other words, the processing liquid is stored in the immersion bath 400 before the substrate W is held by the substrate holding portion 200 at the first height position P1. In the case of storing the processing liquid in the immersion bath 400, for example, the substrate holding portion 200 that does not hold the substrate W may be disposed in the immersion bath 400, and the processing liquid may be stored in the immersion bath 400 by ejecting the processing liquid from the nozzle 38. After the processing liquid is stored in the immersion bath 400, the substrate holding portion 200 may be lifted to hold the substrate W.

In the eighth modification example, the moving mechanism 300 switches the state of the substrate W from the non-immersion state (state in FIG. 31) to the immersion state (state in FIG. 9) by moving (lowering) the substrate holding portion 200 in a state in which the processing liquid is stored in the immersion bath 400. That is, the substrate W is immersed in the processing liquid stored in the immersion bath 400. Specifically, when the substrate holding portion 200 is lowered, the state in which the processing liquid is stored in the immersion bath 400 (state in FIG. 31) changes to the state in which the substrate W is immersed in the processing liquid (state in FIG. 9).

In the eighth modification example, as described above, the moving mechanism 300 switches the state of the substrate W from the non-immersion state to the immersion state in the state in which the processing liquid is stored in the immersion bath 400. That is, the substrate W is lowered and immersed in the processing liquid stored in the immersion bath 400. As a result, it is not necessary to replace the processing liquid in the immersion bath 400 every time the substrate W is immersed. Therefore, the consumption of the processing liquid can be further reduced.

Other configurations, substrate processing methods, and effects of the eighth modification example are the same as those of the first preferred embodiment, the second preferred embodiment, etc.

### Ninth Modification Example

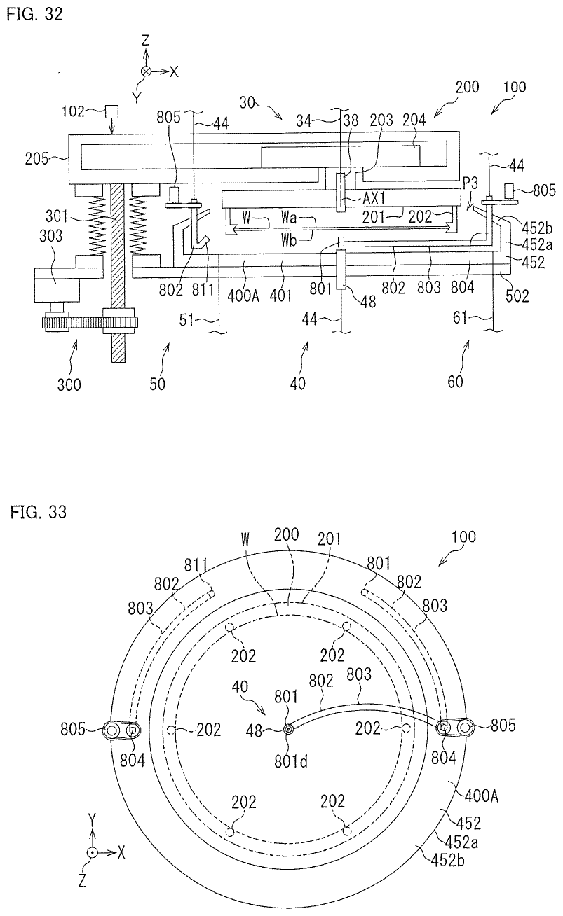

Next, a substrate processing apparatus 100 according to a ninth modification example of the present invention will be described with reference to FIGS. 32 to 34. The ninth modification example is different from the first and second preferred embodiments in that a scan nozzle 801, which is an example of a physical tool, is moved in an immersion bath 400A.

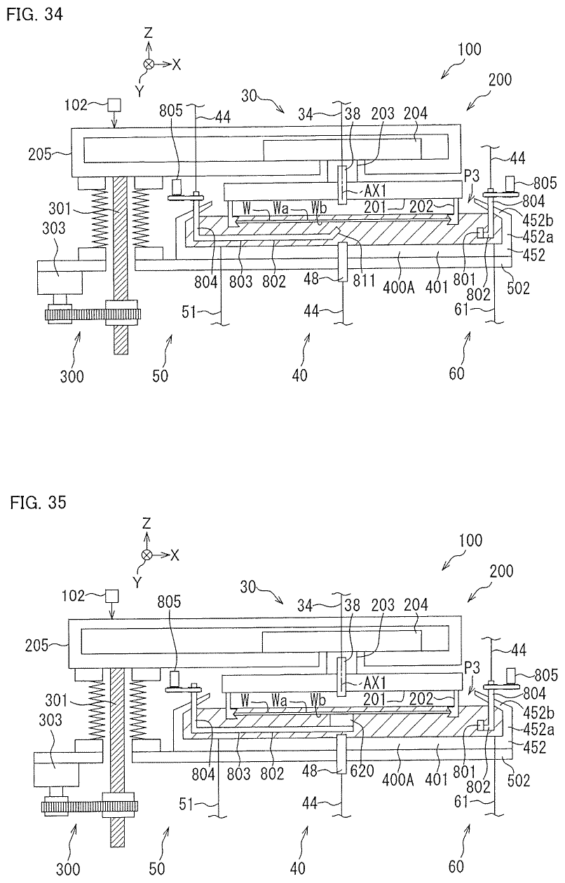

FIGS. 32 to 34 are schematic views illustrating the substrate processing apparatus 100 according to the ninth modification example. FIGS. 32 and 34 are schematic views illustrating a vertical cross section of the immersion bath 400A. FIG. 33 is a schematic plan view of the immersion bath 400A.

The immersion bath 400A has a shape in which the side wall 402 is omitted from the immersion bath 400 and the cup 450 illustrated in FIG. 2. Specifically, as illustrated in FIG. 32, the immersion bath 400A has the bottom wall 401 and the side wall 452. The side wall 452 has a circular cylindrical shape having a vertical center line passing through the center of the substrate W held by the substrate holding portion 200. The bottom wall 401 has a horizontal disk shape by which an opening formed by a lower end of the side wall 452 is closed. The upper surface of the bottom wall 401 is flat from the center line of the side wall 452 to the inner peripheral surface of the side wall 452.

The side wall 452 of the immersion bath 400A includes the circular cylindrical lower wall portion 452a extending vertically and the upper wall portion 452b extending obliquely upward from the upper end of the lower wall portion 452a toward the rotational axis AX1. The upper wall portion 452b vertically faces the outer peripheral portion of the bottom wall 401 with an interval therebetween. The inner diameter of the side wall 452 is the smallest at the circular inner circumferential end of the upper wall portion 452b corresponding to the circular inner circumferential end of the side wall 452. The substrate W and the plurality of chuck pins 202 vertically pass through an opening formed by the inner circumferential end of the side wall 452, that is, a space inside the inner circumferential end of the side wall 452 in a state in which the plurality of chuck pins 202 hold the substrate W.

The second supplying portion 40 supplies the processing liquid to the immersion bath 400A by ejecting the processing liquid toward the lower surface Wb of the substrate W held by the substrate holding portion 200. In addition to or instead of the nozzle 48, the second supplying portion 40 includes the scan nozzle 801 that ejects the processing liquid toward the lower surface Wb of the substrate W held by the substrate holding portion 200, and a scan arm 802 that supports the scan nozzle 801.

The scan nozzle 801 is disposed in the immersion bath 400A. The scan nozzle 801 is supported by the scan arm 802 in the immersion bath 400A. The scan arm 802 is supported by the immersion bath 400A. The scan arm 802 is movable horizontally with respect to the immersion bath 400A. Therefore, the scan nozzle 801 is movable horizontally with respect to the immersion bath 400A. The scan nozzle 801 may be integrated with the scan arm 802 or may be a separate member from the scan arm 802 attached to the scan arm 802.

The scan arm 802 is hollow and forms a flow path for guiding the processing liquid to an ejection port 802d (see FIG. 33) of the scan nozzle 801. That is, a horizontal portion 803 and a vertical portion 804 of the scan arm 802 that will be described later have a cylindrical shape in which a flow path for guiding the processing liquid to the ejection port 802d of the scan nozzle 801 is formed. The ejection port 802d of the scan nozzle 801 may eject the processing liquid directly upward or obliquely upward toward the lower surface Wb of the substrate W held by the substrate holding portion 200.

The scan nozzle 801 is connected to the common piping 44 through the scan arm 802. The common piping 44 is connected to the first chemical liquid piping 41, the second chemical liquid piping 42, and the rinse liquid piping 43 (see FIG. 2). Therefore, the scan nozzle 801 is connected to the first chemical liquid piping 41, the second chemical liquid piping 42, and the rinse liquid piping 43.

When the controlling portion 102 switches any one of the opening/closing valve 45, the opening/closing valve 46, and the opening/closing valve 47 (see FIG. 2) from the closed state to the open state, any one of the first chemical liquid, the second chemical liquid, and the rinse liquid is ejected from the scan nozzle 801. The processing liquid ejected from the scan nozzle 801 is stored in the immersion bath 400A through or without involvement of the lower surface Wb of the substrate W held by the substrate holding portion 200.

The scan arm 802 includes the horizontal portion 803 disposed in the immersion bath 400A and the vertical portion 804 extending vertically upward from the horizontal portion 803. The horizontal portion 803 may have an arc shape having a radius of curvature larger than the radius of curvature of the substrate W and smaller than the radius of curvature of the inner peripheral surface of the lower wall portion 452a of the immersion bath 400A, or may have a shape other than the arc. FIG. 33 illustrates an example of the former. The scan nozzle 801 is supported by the horizontal portion 803 in the immersion bath 400A. The vertical portion 804 is horizontally separated from the scan nozzle 801. The vertical portion 804 vertically penetrates the upper wall portion 452b of the immersion bath 400A. The scan arm 802 is supported by the immersion bath 400A through the vertical portion 804. The scan arm 802 is rotatable with respect to the immersion bath 400A around the vertical center line of the vertical portion 804.

As illustrated in FIG. 33, the second supplying portion 40 includes a horizontal actuator 805 that horizontally moves the scan nozzle 801 with respect to the immersion bath 400A between a processing position (a position indicated by a solid line) and a standby position (a position indicated by an alternate long and two short dashed line) by moving the scan arm 802. The processing position is a position where the processing liquid ejected from the scan nozzle 801 is supplied to the lower surface Wb of the substrate W held by the substrate holding portion 200. The standby position is a position where the processing liquid ejected from the scan nozzle 801 is not supplied to the substrate W held by the substrate holding portion 200. The standby position is a position where the scan nozzle 801 and the scan arm 802 do not overlap the substrate W and the chuck pin 202 when the substrate W held by the substrate holding portion 200 is viewed vertically. When the substrate W held by the substrate holding portion 200 is viewed vertically in a state in which the scan nozzle 801 is disposed at the processing position, the scan nozzle 801 and the scan arm 802 may or may not overlap the substrate W and the substrate holding portion 200. FIG. 33 illustrates an example of the former.

FIG. 33 illustrates an example in which the horizontal actuator 805 is an electric motor. The horizontal actuator 805 is disposed outside the immersion bath 400A. The horizontal actuator 805 is coupled to the vertical portion 804 of the scan nozzle 801. The horizontal actuator 805 may be coupled directly or indirectly to the scan nozzle 801. In the latter case, the horizontal actuator 805 may be coupled to the scan nozzle 801 through a driven pulley concentric with the vertical portion 804 that rotates together with the vertical portion 804, a driving pulley driven by the horizontal actuator 805, and an endless transmission belt that transmits rotation of the driving pulley to the driven pulley. When the horizontal actuator 805 rotates, the scan nozzle 801 moves horizontally by an amount corresponding to a rotation angle of the horizontal actuator 805. The horizontal actuator 805 can stop the scan nozzle 801 at any position within a range from the processing position to the standby position.

The controlling portion 102 causes the substrate processing apparatus 100 to process the substrate W by causing the substrate processing apparatus 100 to execute the substrate processing method of the ninth modification example similar to the substrate processing method of the first or second preferred embodiment.

However, the substrate processing method of the ninth modification example is different from the substrate processing methods of the first and second preferred embodiments in that the processing liquid is ejected from the scan nozzle 801 in addition to or instead of the nozzle 48. In the substrate processing method of the ninth modification example, the controlling portion 102 may cause the scan nozzle 801 located at the processing position to eject the processing liquid while locating the substrate W at the third height position P3 illustrated in FIG. 15 instead of the second height position P2 illustrated in FIG. 7. After moving the scan nozzle 801 from the processing position to the standby position, the controlling portion 102 may lower the substrate W to the second height position P2 illustrated in FIG. 7 to immerse the substrate W in the processing liquid. Both the second height position P2 and the third height position P3 are positions where the substrate W held by the substrate holding portion 200 is disposed at a position lower than the inner peripheral end of the side wall 452 of the immersion bath 400A.

When the scan nozzle 801 is caused to eject the processing liquid toward the lower surface Wb of the substrate W, the processing liquid hits the lower surface Wb of the substrate W. As a result, kinetic energy of the processing liquid, which is an example of physical force, is applied to the lower surface Wb of the substrate W. When the scan nozzle 801 is caused to eject the processing liquid toward the lower surface Wb of the substrate W while rotating the substrate W, the processing liquid flows toward the outer circumference of the lower surface Wb of the substrate W along the lower surface Wb of the substrate W. As a result, the processing liquid is supplied to the entire region of the lower surface Wb of the substrate W.

When the scan nozzle 801 is moved in a state in which the substrate W is being rotated and the scan nozzle 801 is ejecting the processing liquid toward the lower surface Wb of the substrate W, a distance from the center of the lower surface Wb of the substrate W to the hitting position of the processing liquid (a position where the processing liquid ejected from the scan nozzle 801 hits the lower surface Wb of the substrate W) changes. Therefore, by controlling a position and a moving speed of the scan nozzle 801, the lower surface Wb of the substrate W can also be intentionally processed unevenly. For example, the lower surface Wb of the substrate W can be etched to form a concentric distribution of the etching amount that decreases or increases as the etching amount approaches the outer circumference of the substrate W.

As illustrated in FIG. 34, the second supplying portion 40 of the ninth modification example may include a cavitation nozzle 811 which is an example of a physical tool in addition to or instead of the scan nozzle 801. FIG. 34 illustrates an example in which both the scan nozzle 801 and the cavitation nozzle 811 are provided and the scan nozzle 801 and the cavitation nozzle 811 are supported by two separate scan arms 802.

The cavitation nozzle 811 is a nozzle that ejects a liquid containing bubbles such as microbubbles (bubbles within a range of 1 μm to 100 μm) from an ejection port of the cavitation nozzle 811 in a state in which the ejection port is disposed in the processing liquid in the immersion bath 400A, thereby generating cavitation in the processing liquid in the immersion bath 400A due to an increase in pressure applied to the bubbles. When the cavitation is generated in the processing liquid in a state in which the substrate W held by the substrate holding portion 200 is immersed in the processing liquid in the immersion bath 400A, an impact caused by the cavitation is applied to the lower surface Wb of the substrate W.

The cavitation nozzle 811 is disposed in the immersion bath 400A. The ejection port of the cavitation nozzle 811 is disposed in the immersion bath 400A. The cavitation nozzle 811 is supported by the immersion bath 400A through the scan arm 802. The horizontal actuator 805 is coupled to the cavitation nozzle 811 through the scan arm 802.

The horizontal actuator 805 horizontally moves the cavitation nozzle 811 with respect to the immersion bath 400A between the processing position (a position illustrated in FIG. 34) and the standby position by moving the scan arm 802. Details of the standby position are similar to the standby position of the scan nozzle 801. FIG. 34 illustrates an example in which the cavitation nozzle 811 ejects the processing liquid toward the central portion of the lower surface Wb of the substrate W. The cavitation nozzle 811 may eject the processing liquid to any position in the lower surface Wb of the substrate W.

As illustrated in FIG. 34, in the substrate processing method of the ninth modification example, the controlling portion 102 may cause the cavitation nozzle 811 to eject the processing liquid toward the lower surface Wb of the substrate W in a state in which the substrate W is held by the substrate holding portion 200 and immersed in the processing liquid in the immersion bath 400A. In this case, the controlling portion 102 may cause the horizontal actuator 805 to horizontally move the cavitation nozzle 811 while causing the cavitation nozzle 811 to eject the processing liquid. Alternatively, the controlling portion 102 may cause the horizontal actuator 805 to stop the cavitation nozzle 811 at any position within the range from the processing position to the standby position while causing the cavitation nozzle 811 to eject the processing liquid.

Other configurations and other effects of the ninth modification example are similar to those of the first preferred embodiment and the second preferred embodiment.

### Tenth Modification Example

Next, a substrate processing apparatus 100 according to a tenth modification example of the present invention will be described with reference to FIG. 35. The tenth modification example is different from the ninth modification example in that the brush 620 which is an example of a physical tool is moved in the immersion bath 400A.

FIG. 35 is a schematic view illustrating the substrate processing apparatus 100 according to the tenth modification example. The brush 620 is disposed in the immersion bath 400A. The brush 620 is attached to the scan arm 802. The brush 620 is supported by the immersion bath 400A through the scan arm 802. The brush 620 is disposed between the substrate W held by the substrate holding portion 200 and the bottom wall 401 of the immersion bath 400A. The brush 620 and the scan arm 802 are separated upward from the bottom wall 401 of the immersion bath 400A.

The horizontal actuator 805 horizontally moves the brush 620 with respect to the immersion bath 400A between the processing position (a position illustrated in FIG. 35) and the standby position by horizontally moving the scan arm 802. The processing position is a position where the brush 620 comes into contact with the lower surface Wb of the substrate W held by the substrate holding portion 200. The standby position is a position where the brush 620 and the scan arm 802 do not overlap the substrate W and the chuck pin 202 when the substrate W held by the substrate holding portion 200 is viewed vertically. FIG. 35 illustrates an example in which the brush 620 comes into contact with the central portion of the lower surface Wb of the substrate W. The brush 620 may come into contact with any position in the lower surface Wb of the substrate W.

As illustrated in FIG. 35, in the substrate processing method of the ninth modification example, the controlling portion 102 may bring the brush 620 into contact with the lower surface Wb of the substrate W while causing the substrate holding portion 200 to rotate the substrate W in a state in which the substrate W is held by the substrate holding portion 200 and immersed in the processing liquid in the immersion bath 400A. In this case, the controlling portion 102 may cause the horizontal actuator 805 to horizontally move the brush 620 while bringing the brush 620 into contact with the lower surface Wb of the substrate W. Alternatively, the controlling portion 102 may cause the horizontal actuator 805 to stop the brush 620 at any position within the range from the processing position to the standby position while bringing the brush 620 into contact with the lower surface Wb of the substrate W.

Other configurations and other effects of the tenth modification example are similar to those of the first preferred embodiment and the second preferred embodiment.

### Eleventh Modification Example

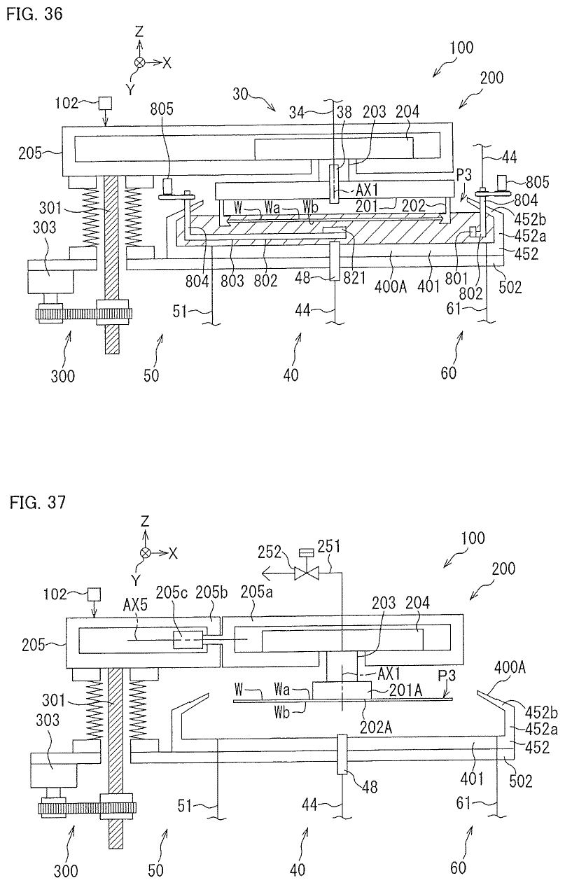

Next, a substrate processing apparatus 100 according to an eleventh modification example of the present invention will be described with reference to FIG. 36. The eleventh modification example is different from the ninth modification example in that an ultrasonic vibrator 821 which is an example of a physical tool is moved in the immersion bath 400A.

FIG. 36 is a schematic view illustrating the substrate processing apparatus 100 according to the eleventh modification example. The ultrasonic vibrator 821 is disposed in the immersion bath 400A. The ultrasonic vibrator 821 is attached to the scan arm 802. The ultrasonic vibrator 821 is supported by the immersion bath 400A through the scan arm 802. The ultrasonic vibrator 821 is disposed between the substrate W held by the substrate holding portion 200 and the bottom wall 401 of the immersion bath 400A. The ultrasonic vibrator 821 and the scan arm 802 are separated upward from the bottom wall 401 of the immersion bath 400A. The ultrasonic vibrator 821 vibrates the processing liquid in the immersion bath 400A to generate cavitation in the processing liquid in the immersion bath 400A.

The horizontal actuator 805 horizontally moves the ultrasonic vibrator 821 with respect to the immersion bath 400A between the processing position (a position illustrated in FIG. 36) and the standby position by horizontally moving the scan arm 802. The processing position is a position where the ultrasonic vibrator 821 vertically faces the lower surface Wb of the substrate W held by the substrate holding portion 200 with an interval therebetween. The standby position is a position where the ultrasonic vibrator 821 and the scan arm 802 do not overlap the substrate W and the chuck pin 202 when the substrate W held by the substrate holding portion 200 is viewed vertically. FIG. 36 illustrates an example in which the ultrasonic vibrator 821 vertically faces the central portion of the lower surface Wb of the substrate W. The ultrasonic vibrator 821 may vertically face any position in the lower surface Wb of the substrate W.

In the substrate processing method of the ninth modification example, the controlling portion 102 may cause the ultrasonic vibrator 821 located at the processing position to generate ultrasonic vibration while causing the substrate holding portion 200 to rotate the substrate W in a state in which the substrate W is held by the substrate holding portion 200 and immersed in the processing liquid in the immersion bath 400A. In this case, the controlling portion 102 may cause the horizontal actuator 805 to horizontally move the ultrasonic vibrator 821 while causing the ultrasonic vibrator 821 to generate ultrasonic vibration. Alternatively, the controlling portion 102 may cause the horizontal actuator 805 to stop the ultrasonic vibrator 821 at any position within the range from the processing position to the standby position while causing the ultrasonic vibrator 821 to generate ultrasonic vibration.

Other configurations and other effects of the eleventh modification example are similar to those of the first preferred embodiment and the second preferred embodiment.

### Twelfth Modification Example

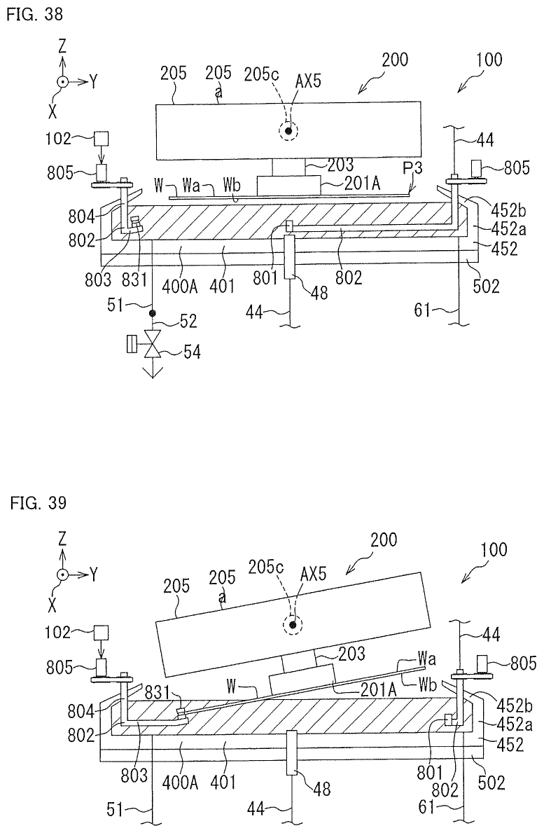

Next, a substrate processing apparatus 100 according to a twelfth modification example of the present invention will be described with reference to FIGS. 37 to 39. The twelfth modification example is different from the ninth modification example in that the outer circumferential portion of the substrate W is polished by a polishing tool 831 (see FIGS. 38 and 39) which is an example of a physical tool while only a portion of the outer circumferential portion of the substrate W is immersed in the processing liquid in the immersion bath 400A.

FIGS. 37 to 39 are schematic views illustrating the substrate processing apparatus 100 according to the twelfth modification example. FIGS. 37 to 39 are schematic views in which the immersion bath 400A, etc., are viewed horizontally. FIGS. 38 and 39 are schematic views in which the immersion bath 400A, etc., are viewed in the left direction of FIG. 37. FIG. 38 illustrates a state in which the substrate holding portion 200 maintains the substrate W in a horizontal posture. FIG. 39 illustrates a state in which the substrate holding portion 200 maintains the substrate W in an inclined posture. Hereinafter, unless otherwise specified, the substrate processing apparatus 100 when the substrate W is maintained in a horizontal posture will be described.

As illustrated in FIG. 37, the substrate holding portion 200 includes a spin base 201A that horizontally holds the substrate W by suctioning the substrate W, instead of the plurality of chuck pins 202 and the spin base 201 illustrated in FIG. 2. In the twelfth modification example, unlike the ninth modification example, the nozzle 38 that ejects the processing liquid toward the upper surface Wa of the substrate W is not provided.

The spin base 201A is a suction base that rotates around the vertical rotational axis AX1 passing through the center of the substrate W in a state in which the upper surface Wa of the substrate W is suctioned onto a lower surface 202A of the spin base 201A. The spin base 201A has a horizontal disk shape having a diameter smaller than the diameter of the substrate W. The center line of the spin base 201A is disposed on the rotational axis AX1. Therefore, the spin base 201A horizontally holds the substrate W in a state in which the outer circumferential portion of the substrate W is located outside the outer peripheral surface of the spin base 201A.

The spin base 201A includes the lower surface 202A in which a plurality of suction ports for sucking a gas are opened. The spin base 201A is connected to a suction piping 251 to which a suction valve 252 is attached. When the suction valve 252 is switched from the closed state to the open state, a suction force of a negative pressure generation source such as a pump or an aspirator is transmitted to the plurality of suction ports through the suction piping 251. The substrate W is suctioned onto the lower surface 202A of the spin base 201A by the suction force transmitted to the plurality of suction ports.

The spin base 201A is disposed at a position lower than the housing 205. The spin base 201A is supported by the electric motor 204 through the shaft 203. The shaft 203 extends upward from the spin base 201A. The electric motor 204 rotates the shaft 203 in the rotation direction to rotate the substrate W and the spin base 201A around the rotational axis AX1.

The housing 205 of the substrate holding portion 200 includes a rotary housing 205a that is relatively rotatable about a horizontal straight line (rotational center AX5) and a support housing 205b. The substrate holding portion 200 includes an electric motor 205c that rotates the rotary housing 205a with respect to the support housing 205b. The electric motor 204 is accommodated in the rotary housing 205a. The electric motor 205c is accommodated in the support housing 205b. The spin base 201A is supported by the rotary housing 205a through the shaft 203 and the electric motor 204. The moving mechanism 300 is coupled to the rotary housing 205a through the support housing 205b.

The rotational center AX5 of the rotary housing 205a with respect to the support housing 205b is a horizontal straight line passing through the center of the substrate W when the substrate W held by the substrate holding portion 200 is viewed vertically. The electric motor 205c rotates the rotary housing 205a with respect to the support housing 205b at a rotation angle of less than 45 degrees around the rotational center AX5. As illustrated in FIGS. 38 and 39, when the electric motor 205c is rotated by a certain angle in the positive direction in a state in which the substrate holding portion 200 maintains the substrate W in a horizontal posture, the posture of the substrate W changes to an inclined posture in which the upper surface Wa and the lower surface Wb of the substrate W are inclined at an angle of less than 45 degrees with respect to the horizontal plane. When the electric motor 205c is rotated by a certain angle in the reverse direction in this state, the posture of the substrate W returns to the horizontal posture in which the upper surface Wa and the lower surface Wb of the substrate W are horizontal. The electric motor 205c is an example of a posture changing actuator. The posture changing actuator may be an electric or pneumatic rotary actuator.

As illustrated in FIGS. 38 and 39, when the electric motor 205c is rotated by a certain angle in the positive direction in a state in which the substrate W in the horizontal posture is close to the processing liquid in the immersion bath 400A, only the lower end portion of the inclined substrate W is immersed in the processing liquid in the immersion bath 400A, and the remaining portion of the substrate W is disposed above the processing liquid. Also in a case where the moving mechanism 300 moves the substrate W in the inclined posture in parallel downward, only the lower end portion of the inclined substrate W is immersed in the processing liquid in the immersion bath 400A, and the remaining portion of the substrate W is disposed above the processing liquid. The lower end portion of the substrate W immersed in the processing liquid in the immersion bath 400A includes the outer circumferential portion of the substrate W, which is also referred to as a bevel portion.

As illustrated in FIGS. 38 and 39, the substrate processing apparatus 100 includes the polishing tool 831 that comes into contact with a target object such as the outer circumferential portion of the substrate W. The polishing tool 831 includes abrasive grains coming into contact with a target object and a surface holding the abrasive grains. The surface holding the abrasive grains may be a surface of at least one of a porous material, bristles, and a nonwoven fabric. The porous material may contain a resin such as polyvinyl alcohol. The polishing tool 831 is attached to the scan arm 802. The polishing tool 831 is supported by the immersion bath 400A through the scan arm 802. The polishing tool 831 is disposed between the substrate W held by the substrate holding portion 200 and the bottom wall 401 of the immersion bath 400A. The polishing tool 831 and the scan arm 802 are separated upward from the bottom wall 401 of the immersion bath 400A.

The horizontal actuator 805 horizontally moves the polishing tool 831 with respect to the immersion bath 400A between the processing position (a position illustrated in FIG. 39) and the standby position (a position illustrated in FIG. 38) by horizontally moving the scan arm 802. The processing position is a position where the polishing tool 831 comes into contact with the outer circumferential portion of the substrate W in the inclined posture. The standby position is a position where the polishing tool 831 and the scan arm 802 do not overlap the substrate W when the substrate W horizontally held by the substrate holding portion 200 is viewed vertically.

The controlling portion 102 causes the substrate processing apparatus 100 to process the substrate W by causing the substrate processing apparatus 100 to execute the substrate processing method of the twelfth modification example similar to the substrate processing method of the ninth modification example.

However, in the twelfth modification example, since the nozzle 38 that ejects the processing liquid toward the upper surface Wa of the substrate W is not provided, the substrate processing method of the twelfth modification example is different from the substrate processing method of the ninth modification example in that the processing liquid is not ejected toward the upper surface Wa of the substrate W. The substrate processing method of the twelfth modification example is different from the substrate processing method of the ninth modification example also in that only a portion of the substrate W is immersed in the processing liquid instead of immersing the entire substrate W in the processing liquid.

When only a portion of the substrate W is immersed in the rinse liquid, as illustrated in FIG. 38, the controlling portion 102 causes the scan nozzle 801 to eject the rinse liquid toward the lower surface Wb of the substrate W in the horizontal posture while causing the substrate holding portion 200 to rotate the substrate W in a state in which the substrate W is horizontally held by the substrate holding portion 200 and is disposed at the third height position P3, and the opening/closing valve 54 for discharging the processing liquid in the immersion bath 400A is in the open state. Thereafter, the controlling portion 102 switches the opening/closing valve 54 from the open state to the closed state while causing the scan nozzle 801 to eject the rinse liquid. As a result, the rinse liquid is accumulated in the immersion bath 400A.

When the rinse liquid in the immersion bath 400A does not come into contact with the substrate W located at the third height position P3 and the rinse liquid is accumulated in the immersion bath 400A by an amount in which the polishing tool 831 located at the standby position is immersed in the rinse liquid in the immersion bath 400A, the controlling portion 102 causes the scan nozzle 801 to stop ejection of the rinse liquid. Thereafter, as illustrated in FIG. 39, the controlling portion 102 causes the electric motor 205c to change the posture of the substrate W from the horizontal posture to the inclined posture. As a result, the substrate W changes from the non-immersion state to the partial immersion state. That is, only the lower end portion of the inclined substrate W is immersed in the rinse liquid in the immersion bath 400A, and the remaining portion of the substrate W is disposed above the rinse liquid. An angle of the inclined substrate W is a value at which the lower end portion of the inclined substrate W is disposed at the same height position as a portion of the polishing tool 831 located at the standby position.

The controlling portion 102 causes the horizontal actuator 805 to move the polishing tool 831 from the standby position to the processing position in a state in which only the lower end portion of the inclined substrate W is immersed in the rinse liquid in the immersion bath 400A and the substrate holding portion 200 is rotating the substrate W. As a result, the polishing tool 831 comes into contact with the outer circumferential portion of the substrate W and is rubbed against the outer circumferential portion of the substrate W over the entire circumference of the substrate W. The rinse liquid in the immersion bath 400A enters the interface between the polishing tool 831 and the substrate W. As a result, the outer circumferential portion of the substrate W can be polished while being cooled. A chemomechanical effect can also occur. In order to generate a chemomechanical effect, a disk-shaped glass substrate may be held by the substrate holding portion 200.

After the outer circumferential portion of the substrate W is polished by the polishing tool 831, the controlling portion 102 performs a series of steps (steps S10 to S13 illustrated in FIG. 5) from discharge of the rinse liquid to carrying-out of the substrate W in the same manner as the substrate processing method of the ninth modification example (in the same manner as the substrate processing method of the first or second preferred embodiment). In addition to or instead of the timing of supplying the rinse liquid to the lower surface Wb of the substrate W held by the substrate holding portion 200, the controlling portion 102 may polish the outer circumferential portion of the substrate W with the polishing tool 831 as described above when supplying the chemical liquid to the lower surface Wb of the substrate W held by the substrate holding portion 200.

Other configurations and other effects of the twelfth modification example are similar to those of the first preferred embodiment and the second preferred embodiment.

The preferred embodiments of the present invention have been described above with reference to the drawings. However, the present invention is not limited to the above preferred embodiments, and can be implemented in various aspects without departing from the concept thereof. In addition, various inventions can be formed by appropriately combining a plurality of constituents disclosed in the above preferred embodiments. For example, some constituents may be deleted from all the constituents described in the preferred embodiments. Further, constituents across different preferred embodiments may be combined as appropriate. The drawings mainly illustrate the respective constituents schematically for ease of understanding and there are cases where thicknesses, lengths, numbers, intervals, etc., of the respective constituents illustrated differ from actual ones due to convenience of drawing preparation. The materials, the shapes, the dimensions, etc., of the respective constituents described in the above preferred embodiments are only examples, are not restricted in particular, and can be changed variously within a scope of practically not deviating from the effects of the present invention.

For example, in the above preferred embodiments, an example in which the moving mechanism 300 moves the substrate holding portion 200 has been described, but the present invention is not limited thereto. For example, the moving mechanism 300 may move the immersion bath 400. That is, the moving mechanism 300 may relatively move the substrate holding portion 200 and the immersion bath 400. At that time, the moving mechanism 300 may move either the substrate holding portion 200 or the immersion bath 400, or may move both the substrate holding portion 200 and the immersion bath 400.

In addition, in the above preferred embodiments, an example in which the substrate W is rotated when the processing liquid is ejected onto the substrate W has been described, but the present invention is not limited thereto. When the processing liquid is ejected onto the substrate W, the substrate W need not be rotated.

In addition, in the above preferred embodiments, an example in which the cup 450 is cleaned by causing the rinse liquid to overflow has been described, but the present invention is not limited thereto. The rinse liquid need not overflow.

In addition, for example, in the first preferred embodiment, an example in which a drying liquid and a gas are not ejected to the substrate W when the substrate W is dried has been described, but the present invention is not limited thereto. In the first preferred embodiment, when the substrate W is dried, a drying liquid and/or a gas may be ejected.

In addition, in the above preferred embodiments, an example in which the chemical liquid and the rinse liquid are ejected onto the substrate W has been described, but the present invention is not limited thereto. For example, just either the chemical liquid or the rinse liquid may be ejected onto the substrate W. That is, the substrate W may be processed with just either the chemical liquid or the rinse liquid. In this case, the processing liquid (the chemical liquid or the rinse liquid) stored in the immersion bath 400 need not be replaced for each substrate W. In addition, in this case, the substrate W may be immersed in the stored processing liquid.

In addition, in the above preferred embodiments, an example in which the first chemical liquid, the second chemical liquid, and the rinse liquid are ejected from the same nozzle (nozzle 38, nozzle 48) has been described, but the present invention is not limited thereto. For example, a nozzle that ejects the first chemical liquid, a nozzle that ejects the second chemical liquid, and a nozzle that ejects the rinse liquid may be separately provided.

In addition, in the above preferred embodiments, an example in which the chuck pin 202 is driven by the chuck driving mechanism 210 including the driving magnet 211, the driven magnet 212, and the lifting/lowering plate 213 has been described, but the present invention is not limited thereto. A chuck driving mechanism driving the chuck pin 202 is not particularly limited. For example, a motor (chuck driving mechanism) that rotates the chuck pin 202 may be provided on the spin base 201.

In addition, for example, in the fourth modification example to the seventh modification example, an example in which the temperature decrease of the processing liquid is suppressed by the lid 710, the lid 720, the lid 730, or the spin base 201 has been described, but the present invention is not limited thereto. For example, a flow path of an exhaust piping of the gas discharge portion 130 may be closed, or the driving of an exhaust fan may be stopped. Also in this case, since it is possible to suppress a gas from being drawn into the inner space 450a of the cup 450, it is possible to suppress a decrease in the temperature of the processing liquid in the immersion bath 400.

In addition, in the above preferred embodiments, an example in which the substrate W is immersed in the processing liquid while the substrate W is held by the substrate holding portion 200 has been described, but the present invention is not limited thereto. For example, as described in the fourth modification example, the substrate W may be immersed in the processing liquid in a state in which the substrate W is not held by the substrate holding portion 200.

In the ninth modification example to the twelfth modification example, after applying a physical force to the lower surface Wb of the substrate W, the controlling portion 102 may cause the scan nozzle 801 to eject a rinse liquid such as pure water (deionized water (DIW)) toward the lower surface Wb of the substrate W held by the substrate holding portion 200. For example, after causing the cavitation nozzle 811 to eject the rinse liquid, the controlling portion 102 may cause the scan nozzle 801 to eject the rinse liquid.

In the ninth modification example to the twelfth modification example, the controlling portion 102 may store the processing liquid ejected from the nozzle 48 in the immersion bath 400A in addition to or instead of the processing liquid ejected from the scan nozzle 801. The controlling portion 102 may provide a period for storing the processing liquid ejected from either the scan nozzle 801 or the nozzle 48 in the immersion bath 400A and a period for storing the processing liquid ejected from both the scan nozzle 801 and the nozzle 48 in the immersion bath 400A.

The present invention is suitably used for a substrate processing apparatus and a substrate processing method.

What is claimed is:

1. A substrate processing apparatus comprising:
a substrate holding portion that holds and rotates a substrate;
an immersion bath that stores a processing liquid, accommodates the substrate, and immerses the substrate in the processing liquid;
a processing liquid supplying portion that supplies the processing liquid to the immersion bath; and
a moving mechanism that relatively moves the substrate holding portion and the immersion bath, wherein
the moving mechanism switches a state of the substrate between a non-immersion state in which the substrate is located outside the immersion bath and an immersion state in which the substrate is located inside the immersion bath and immersed in the processing liquid by moving the substrate holding portion or the immersion bath.

2. The substrate processing apparatus according to claim 1, wherein the substrate holding portion includes a base disposed above the substrate, and a plurality of chuck pins protruding downward from the base and holding a circumferential edge of the substrate.

3. The substrate processing apparatus according to claim 2, wherein
the processing liquid supplying portion includes an upper nozzle that ejects the processing liquid toward an upper surface of the substrate, and
the upper nozzle is provided on the base.

4. The substrate processing apparatus according to claim 3, wherein
the substrate holding portion rotates the substrate by a rotation of the base, and
the upper nozzle is disposed at a central portion of the base.

5. The substrate processing apparatus according to claim 1, wherein the processing liquid supplying portion ejects the processing liquid toward the substrate to store the processing liquid in the immersion bath.

6. The substrate processing apparatus according to claim 5, wherein the processing liquid supplying portion ejects the processing liquid toward an upper surface and a lower surface of the substrate to store the processing liquid in the immersion bath.

7. The substrate processing apparatus according to claim 5, wherein the processing liquid supplying portion ejects the processing liquid toward the substrate and stores the processing liquid in the immersion bath in a state in which the substrate holding portion rotates the substrate.

8. The substrate processing apparatus according to claim 1, further comprising:
a liquid discharge portion that is connected to a lower portion of the immersion bath and drains the processing liquid in the immersion bath, wherein
when the liquid discharge portion drains the processing liquid in the immersion bath, the processing liquid supplying portion ejects the processing liquid toward the substrate.

9. The substrate processing apparatus according to claim 1, further comprising:
a processing liquid cup provided around a periphery of the immersion bath, wherein
the processing liquid includes a rinse liquid, and
the processing liquid supplying portion supplies the rinse liquid to the immersion bath in a state in which the rinse liquid is stored in the immersion bath, and causes the rinse liquid to overflow from the immersion bath.

10. The substrate processing apparatus according to claim 1, further comprising:
a brush disposed in the immersion bath, wherein
the immersion bath includes a bottom wall and a side wall extending upward from a peripheral edge portion of the bottom wall, and
the brush is disposed on an upper surface of the bottom wall, and
the brush comes into contact with a lower surface of the substrate and cleans the lower surface of the substrate in a state in which the substrate is immersed in the processing liquid stored in the immersion bath.

11. The substrate processing apparatus according to claim 10, wherein the substrate holding portion rotates the substrate in a state in which the lower surface of the substrate is in contact with the brush.

12. The substrate processing apparatus according to claim 1, further comprising:
a processing liquid cup provided around the periphery of the immersion bath and having an inner circumferential edge that forms an opening through which the substrate is able to pass;
a gas discharge portion that discharges a gas in the processing liquid cup; and
a lid that covers the inner circumferential edge.

13. The substrate processing apparatus according to claim 12, wherein the lid is provided on the substrate holding portion.

14. The substrate processing apparatus according to claim 12, further comprising a lid moving mechanism that moves the lid separately from the substrate holding portion.

15. The substrate processing apparatus according to claim 1, wherein the moving mechanism switches the state of the substrate from the non-immersion state to the immersion state by moving the substrate holding portion or the immersion bath in a state in which the processing liquid is stored in the immersion bath.

16. The substrate processing apparatus according to claim 1, further comprising:
a physical tool that is disposed inside the immersion bath and applies a physical force to a lower surface of the substrate held by the substrate holding portion; and
a horizontal actuator that horizontally moves the physical tool inside the immersion bath.

17. The substrate processing apparatus according to claim 16, wherein the physical tool includes at least one of a scan nozzle that ejects the processing liquid toward the lower surface of the substrate held by the substrate holding portion, a cavitation nozzle that generates cavitation in the processing liquid in the immersion bath by ejecting the processing liquid containing bubbles in the processing liquid in the immersion bath, a brush that comes into contact with the lower surface of the substrate held by the substrate holding portion, an ultrasonic vibrator that generates ultrasonic vibration in the processing liquid in the immersion bath, and a polishing tool that comes into contact with an outer circumferential portion of the substrate held by the substrate holding portion.

18. The substrate processing apparatus according to claim 1, wherein
the moving mechanism includes a posture changing actuator that changes a posture of the substrate between a horizontal posture in which the substrate is horizontal and an inclined posture in which the substrate is inclined with respect to a horizontal plane by rotating the substrate held by the substrate holding portion around a horizontal straight line, and
the immersion state includes a partial immersion state in which the substrate is located inside the immersion bath and only a portion of the outer circumferential portion of the substrate is immersed in the processing liquid.

19. A substrate processing method comprising:
rotatably holding a substrate;
relatively moving the substrate and an immersion bath by a moving mechanism;
storing a processing liquid in the immersion bath; and
immersing the substrate in the immersion bath, wherein
when relatively moving the substrate and an immersion bath, the moving mechanism switches a state of the substrate between a non-immersion state in which the substrate is located outside the immersion bath and an immersion state in which the substrate is located inside the immersion bath and immersed in the processing: liquid by moving the substrate or the immersion bath.

20. The substrate processing method according to claim 19, wherein when storing the processing liquid in the immersion bath, the processing liquid is stored in the immersion bath by ejecting the processing liquid toward the substrate.
